(19) United States
(12) Patent Application Publication
(10) Pub. No.: US 2015/0340614 A1
(43) Pub. Date: Nov. 26, 2015

(54) BINUCLEAR METAL(I) COMPLEXES FOR OPTOELECTRONIC APPLICATIONS

(71) Applicant: CYNORA GMBH, Bruchsal (DE)

(72) Inventors: Daniel Volz, Karlsruhe (DE); Andreas Jacob, Karlsruhe (DE); Thomas Baumann, Karlsruhe (DE); Tobias Grab, Karlsruhe (DE)

(21) Appl. No.: 14/655,859

(22) PCT Filed: Dec. 16, 2013
(86) PCT No.: PCT/EP2013/076682

§ 371 Date: Jun. 26, 2015

(30) Foreign Application Priority Data
Dec. 27, 2012 (EP) 12199403.2
May 8, 2013 (EP) 13167032.5

(51) Int. Cl. H01L 51/00; C07F 1/08; C07F 9/6596

(52) U.S. Cl. CPC H01L 51/009; C07F 9/6596; C07F 1/08; H01L 51/0091; H01L 51/5012

(57) ABSTRACT

Metal(I) complexes of the M₂X₂(E∩D)₂ form, having a structure of formula A

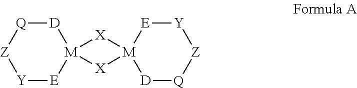

The metal(I) complexes may be used in optoelectronic components, particularly for use in organic light emitting diodes (OLEDs).

The invention relates to binuclear metal(I) complexes of the general formula A, in particular for the use in optoelectronic devices.

### INTRODUCTION

A drastic change in the area of display-screen and lighting technology is currently becoming apparent. It will be possible to manufacture flat displays or illuminated surfaces having a thickness of less than 0.5 mm. These are notable for many fascinating properties. For example, it will be possible to achieve illuminated surfaces in the form of wallpaper with very low energy consumption. Moreover color visual display units will be producible with hitherto unachievable colorfastness, brightness and viewing angle independence, with low weight and with very low power consumption. It will be possible to configure the visual display units as micro-displays or large visual display units of several square meters in area in rigid form or flexibly, or else as transmission or reflection displays. In addition, it will be possible to use simple and cost-saving production processes such as screen printing or inkjet printing or vacuum sublimation. This will enable very inexpensive manufacture compared to conventional flat screens. This new technology is based on the principle of the OLEDs, the Organic Light Emitting Diodes, which are illustrated in FIG. 1 schematically and simplified.

Such devices predominantly consist of organic layers, as shown schematically and in simplified form in FIG. 1. At a voltage of, for example, 5 V to 10 V, negative electrons pass from a conductive metal layer, for example from an aluminum cathode, into a thin electron conduction layer and migrate in the direction of the positive anode. This consists, for example, of a transparent but electrically conductive thin indium tin oxide layer, from which positive charge carriers, so-called holes, migrate into an organic hole conduction layer. These holes move in the opposite direction compared to the electrons, specifically toward the negative cathode. In a middle layer, the emitter layer, which likewise consists of an organic material, there are additionally special emitter molecules at which, or close to which, the two charge carriers recombine and lead to uncharged but energetically excited states of the emitter molecules. The excited states then release their energy as bright emission of light, for example in a blue, green or red color. White light emission is also achievable. In some cases, it is also possible to dispense with the emitter layer when the emitter molecules are present in the hole or electron conduction layer.

The novel OLED devices can be configured with a large area as illumination bodies, or else in exceptionally small form as pixels for displays. A crucial factor for the construction of highly effective OLEDs are the luminous materials used (emitter molecules). These can be implemented in various ways, using purely organic or organometallic molecules, as well as complexes. It can be shown that the light yield of the OLEDs can be much greater with organometallic substances, so-called triplet emitters, than for purely organic materials. Due to this property, the further development of the organometallic materials is of high significance. The function of OLEDs has been described very frequently.^{[i-vi]} Using organometallic complexes with high emission quantum yield (transitions including the lowermost triplet states to the singlet ground states), it is possible to achieve a particularly high efficiency of the device. These materials are frequently referred to as triplet emitters or phosphorescent emitters. This has been known for some time.^{[i-v]} For triplet emitters, many property rights have already been applied for and granted.^{[ ]}

Copper complexes of the Cu₂X₂L₄, Cu₂X₂L′₂ and Cu₂X₂L₂L′ form (L=phosphine, amine, imine ligand; L′=bidentate phosphine, imine, amine ligand, see below) are already known in the prior art.

They exhibit intense luminescence on excitation with UV light. The luminescence can originate from an MLCT, CC (cluster centered) or XLCT (halogen-to-ligand charge transfer) state, or a combination thereof. Further details of similar Cu(I) systems can be found in the literature.^{[xx]} In the case of the related [Cu₂X₂(PPh₃)₂nap] complex (nap=1,8-naphthyridine, X=Br, I), a transition between the molecular orbital of the {Cu₂X₂} unit (Cu d and halogen p orbitals) and the π* orbitals of the nap group is discussed.^{[xxi]}

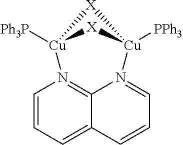

Example of a structure of the compleses of the Cu₂X₂L₂L'form (L=PPh₃, L'=1,8-naphthyridine, X=Br, I)

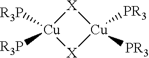

Examples of complexes of the Cu₂X₂L₄ form (L =PR₃, X=Cl, Br, or I)

Triplet emitters have great potential for generation of light in displays (as pixels) and in illuminated surfaces (for example as luminous wallpaper). Very many triplet emitter materials have already been patented, and are now also being used technologically in devices. The present solutions have disadvantages and problems, specifically in the following areas:
long-term stability of the emitters in the OLED devices,
thermal stability,
chemical stability to water and oxygen,
availability of important emission colors,
manufacturing reproducibility,
achievability of high efficiency at high current densities,
achievability of very high luminances,
high cost of the emitter materials,
emitter materials are toxic, and
syntheses are complex.

Against this background, it was an object of the present invention to overcome at least some of the abovementioned disadvantages.

### DESCRIPTION OF THE INVENTION

The problem underlying the invention is solved by the provision of binuclear metal(I) complexes of the M₂X₂(E∩D)₂ form, which comprise a structure according to formula A or are of a structure of formula A:

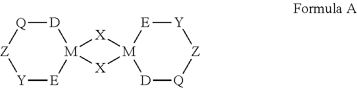

In formula A (subsequently also denoted as M₂X₂(E∩D)₂) E∩D stands, independently from each other, for a bidentate chelating ligand, which binds to the M₂X₂-core via a donor atom D* and a donor atom E*, which are selected independently from each other from the group consisting of N (wherein N is no imine nitrogen atom or part of an N-heteroaromatic ring), P, C*, O, S, As and Sb, wherein the two donor atoms D* and E* are different from each other and are bound via the three units Q, Y, Z and thus result in a bidentate ligand, and wherein in a particular embodiment the following combinations of D* and E* are allowed:

| D* = | N | N | N | N | N | N | P | P | P | P | P | C* | C* | C* |
|---|---|---|---|---|---|---|---|---|---|---|---|---|---|---|
| E* = | P | C* | O | S | As | Sb | N | C* | O | As | Sb | N | P | O |
| D* = | C* | C* | C* | O | O | O | O | O | O | S | S | S | S | S |
| E* = | S | As | Sb | N | P | C* | S | As | Sb | N | C* | O | As | Sb |

| | | | | | | | | | | | | |
|---|---|---|---|---|---|---|---|---|---|---|---|---|
| D* = | As | As | As | As | As | As | Sb | Sb | Sb | Sb | Sb | Sb |
| E* = | N | P | C* | O | S | Sb | N | P | C* | O | S | As |

X stands independently from each other for Cl, Br, I, CN, OCN, SCN, alkynyl and/or N₃, M stands independently from each other for Cu and Ag. C* stands for a divalent carbene carbon atom. ∩ is a threepart unit consisting of Q, Y and Z, which are bound to each other and are independently from each other selected from the group consisting of NR, O, S and PR as well as alkyl (also branched or cyclic), heteroalkyl, aryl, heteroaryl, alkenyl, alkynyl groups or substituted alkyl (also branched or cyclic), heteroalkyl, aryl, heteroaryl and alkenyl groups (with substituents such as halogens or deuterium, alkyl groups (also branched or cyclic), heteroalkyl, aryl, heteroaryl groups), and further generally known donor and acceptor groups such as, for example, amines, carboxylates and their esters, and CF₃ groups. Both ligands E∩D can also be further substituted and/or annulated and/or bound to each other, so that a tetradentate ligand results.

Q is bonded to D as well as Z, wherein the first bond is formed between an atom Q* of the substituent Q and an atom D* of substituent D, and wherein a second bond is formed between an atom Q* of substituent Q and an atom Z* of substituent Z. The same applies for Y, a first bond is formed between an atom Y* of substituent Y and an atom E* of substituent E, and a second bond is formed between an atom Y* of substituent Y and an atom Z* of substituent Z. The same applies for Z, a first bond is formed between an atom Z* of substituent Z and an atom Q* of substituent Q*, and a second bond is formed between an atom Z* of substituent Z and an atom Y* of substituent Y. Q*, Y* and Z* are independently from each other selected from the group consisting of C, N, O, S and P.

The following combinations of directly adjacent atoms D*, E*, Q*, Y* and Z* are not allowed in one embodiment of the invention: P—N, N—As, N—Sb, O—O, P—P, P—As, P—Sb.

Each R is independently from each other selected from the group consisting of hydrogen, halogen and substituents, which are bound directly or via oxygen (—OR), nitrogen (—NR₂), silicon (—SiR₃) or sulfur atoms (—SR) as well as alkyl (also branched or cyclic), heteroalkyl, aryl, heteroaryl, alkenyl, alkynyl groups or substituted alkyl (also branched or cyclic), heteroalkyl, aryl, heteroaryl and alkenyl groups (with substituents such as halogens or deuterium, alkyl groups (also branched or cyclic), heteroalkyl, aryl, heteroaryl groups), and further generally known donor and acceptor groups such as, for example, amines, carboxylates and their esters, and CF₃-groups, which are optionally further substituted and/or annulated.

The difference of D and E results in an asymmetric ligand and hence a complex of very low symmetry (little symmetry operations possible), which has a very low tendency to crystalize in contrast to highly-symmetric complexes (various symmetry operations possible). Since materials for optoelectronic devices such as OLEDs have to form amorphous layers because polycrystalline areas eliminate formed excitons radiationless, compounds with high crystallinity are unsuitable, since separation effects and concentration quenching can occur here. In non-stable films, which crystallize during OLED operation, the grain boundary of the crystals can act as trap states. Therefore, the stability of the amorphous state is an important criterion for the development of organic functional materials such as OLEDs. Thermal stress during the operation of an OLED can lead to a transition of the metastable amorphous state to the thermodynamically stable crystal. This results in extensive consequences for the lifetime of the device. The grain boundaries of individual crystals represent defects at which the transport of the charge carriers is disrupted. The reorganization of the layers accompanying the crystallization also leads to a reduced contact of the layers among themselves and with the electrodes. During operation, this gradually leads to the appearance of dark spots and in the end to the destruction of the OLED.

Thus, the object of the present invention was to overcome the disadvantages described above for the use of symmetrical and thus easier crystallizable complexes and to provide emitter materials, which do not comprise these disadvantageous properties due to their clearly lower symmetry.

The ligand E∩D can optionally be substituted, in particular with functional groups, which improve the charge carrier transport and/or groups, which increase the solubility of the metal(I) complex in common organic solvents for the production OLED components. Common organic solvents comprise, besides alcohols, ethers, alkanes as well as halogenated aliphatic and aromatic hydrocarbons and alkylated aromatic hydrocarbons, in particular toluene, chlorobenzene, dichlorobenzene, mesitylene, xylene, tetrahydrofuran, phenetole, and propiophenone.

Particular embodiments of the binuclear metal(I) complexes of formula A according to the invention are represented by the compounds of formulas I to IX and are explained below.

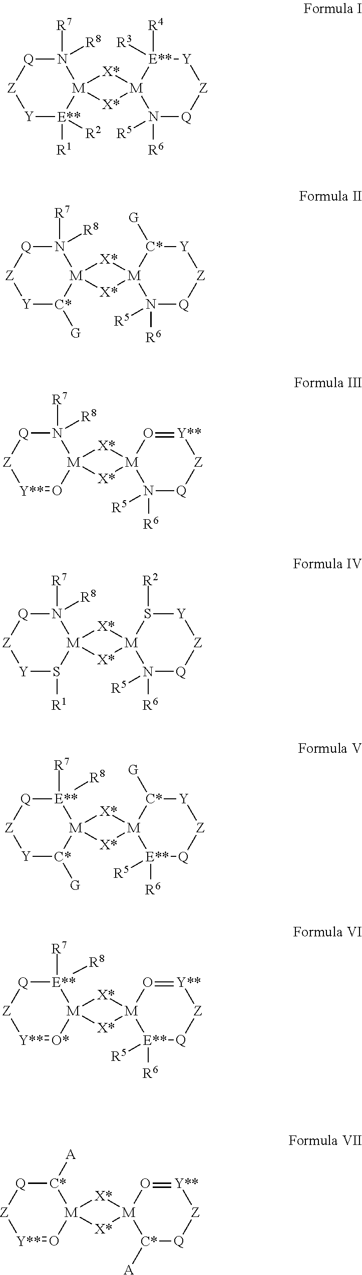

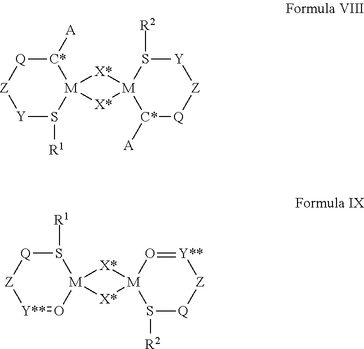

with:
X*=independently from each other selected from the group consisting of Cl, Br, I, CN, OCN, SCN, alkynyl und N₃;
M=independently from each other selected from the group consisting of Cu and Ag;
E**=independently from each other selected from the group consisting of P, As and Sb;
C*=a divalent carbene carbon atom;
A and G=independently from each other substituents selected from the group consisting of NRR′, OR, SR and PRR′ as well as alkyl (also branched or cyclic), heteroalkyl, aryl, heteroaryl, alkenyl, alkynyl groups or substituted alkyl (also branched or cyclic), heteroalkyl, aryl, heteroaryl and alkenyl groups (with substituents such as halogens or deuterium, alkyl groups (also branched or cyclic), heteroalkyl, aryl, heteroaryl groups), and further generally known donor and acceptor groups such as, for example, amines, carboxylates and their esters, and CF₃-groups, which are optionally further substituted and/or annulated;
Q, Y and Z=independently from each other substituents selected from the group consisting of NR, O, S and PR as well as alkyl (also branched or cyclic), heteroalkyl, aryl, heteroaryl, alkenyl, alkynyl groups or substituted alkyl (also branched or cyclic), heteroalkyl, aryl, heteroaryl and alkenyl groups (with substituents such as halogens or deuterium, alkyl groups (also branched or cyclic), heteroalkyl, aryl, heteroaryl groups), and further generally known donor and acceptor groups such as, for example, amines, carboxylates and their esters, and CF₃-groups, which are optionally further substituted and/or annulated;
Y**=independently from each other selected from the group consisting of CR, N, PRR′, SR, S(O)R;
R and R′=independently from each other selected from the group consisting of hydrogen, halogen and substituents, which are bound directly or via oxygen (—OR), nitrogen (—NR₂), silicon (—SiR₃) or sulfur atoms (—SR) as well as alkyl (also branched or cyclic), heteroalkyl, aryl, heteroaryl, alkenyl, alkynyl groups or substituted alkyl (also branched or cyclic), heteroalkyl, aryl, heteroaryl and alkenyl groups (with substituents such as halogens or deuterium, alkyl groups (also branched or cyclic), heteroalkyl, aryl, heteroaryl groups), and further generally known donor and acceptor groups such as, for example, amines, carboxylates and their esters, and CF₃-groups, which are optionally further substituted and/or annulated;

R¹-R⁸=each independently from each other selected from the group consisting of hydrogen, halogen and substituents, which are bound directly or via oxygen (—OR), nitrogen (—NR₂), silicon (—SiR₃) or sulfur atoms (—SR) as well as alkyl (also branched or cyclic), heteroalkyl, aryl, heteroaryl, alkenyl, alkynyl groups or substituted alkyl (also branched or cyclic), heteroalkyl, aryl, heteroaryl and alkenyl groups (with substituents such as halogens or deuterium, alkyl groups (also branched or cyclic), heteroalkyl, aryl, heteroaryl groups), and further generally known donor and acceptor groups such as, for example, amines, carboxylates and their esters, and CF₃-groups, which are optionally further substituted and/or annulated. The groups R¹-R⁸ can optionally also lead to annulated ring systems.

The unit QC*A is in one embodiment selected from the group consisting of:

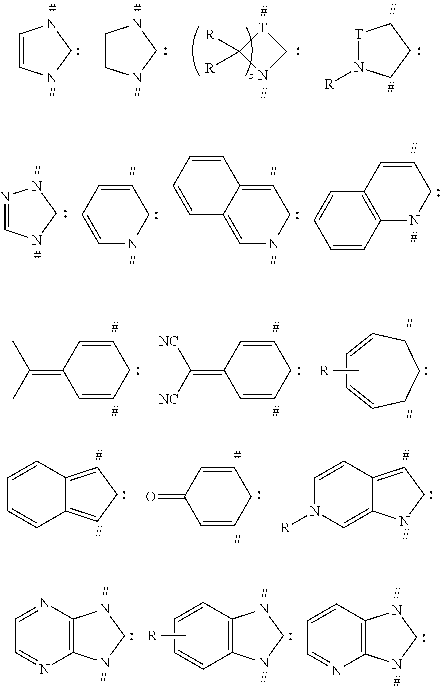

wherein the two dots “:” stand for a divalent carbene carbon atom, which coordinates to the metal, and the linkage of Q with Z takes place at one of the positions marked with # and thus A represents the other neighboring atom of the carbene carbon atom, which is then substituted with a group R, which is selected from the group consisting of hydrogen, halogen and substituents which are bound directly or via oxygen (—OR), nitrogen (—NR₂), silicon (—SiR₃) or sulfur atoms (—SR) as well as alkyl (also branched or cyclic), heteroalkyl, aryl, heteroaryl, alkenyl, alkynyl groups or substituted alkyl (also branched or cyclic), heteroalkyl, aryl, heteroaryl and alkenyl groups (with substituents such as halogens or deuterium, alkyl groups (also branched or cyclic), heteroalkyl, aryl, heteroaryl groups), and further generally known donor and acceptor groups such as, for example, amines, carboxylates and their esters, and CF₃-groups, which are optionally further substituted and/or annulated;
each further R is independently from each other also selected from the group consisting of hydrogen, halogen and substituents which are bound directly or via oxygen (—OR), nitrogen (—NR₂), silicon (—SiR₃) or sulfur atoms (—SR) as well as alkyl (also branched or cyclic), heteroalkyl, aryl, heteroaryl, alkenyl, alkynyl groups or substituted alkyl (also branched or cyclic), heteroalkyl, aryl, heteroaryl and alkenyl groups (with substituents such as halogens or deuterium, alkyl groups (also branched or cyclic), heteroalkyl, aryl, heteroaryl groups), and further generally known donor and acceptor groups such as, for example, amines, carboxylates and their esters, and CF₃-groups, which are optionally further substituted and/or annulated;
T is selected from the group consisting of CR₂, NR and SR, wherein each R independently from each other is selected from the group consisting of hydrogen, halogen and substituents which are bound directly or via oxygen (—OR), nitrogen (—NR₂), silicon (—SiR₃) or sulfur atoms (—SR) as well as alkyl (also branched or cyclic), heteroalkyl, aryl, heteroaryl, alkenyl, alkynyl groups or substituted alkyl (also branched or cyclic), heteroalkyl, aryl, heteroaryl and alkenyl groups (with substituents such as halogens or deuterium, alkyl groups (also branched or cyclic), heteroalkyl, aryl, heteroaryl groups), and further generally known donor and acceptor groups such as, for example, amines, carboxylates and their esters, and CF₃-groups, which are optionally further substituted and/or annulated;
and z stands for the integer 1, 2, 3 or 4.

The bidentate ligand E∩D can optionally be substituted, in particular with functional groups which improve the charge carrier transport and/or groups which increase the solubility of the metal(I) complex in common organic solvents for the production of OLED components. Common organic solvents comprise besides alcohols, ethers, alkanes as well as halogenated aliphatic and aromatic hydrocarbons and alkylated aromatic hydrocarbons, in particular toluene, chlorobenzene, dichlorobenzene, mesitylene, xylene, tetrahydrofuran, phenetole, propiophenone.

The stability and rigidity of the metal(I) complex is strongly increased by the coordination of the bidenate ligand E∩D. The great advantage in the case of the use of copper as the central metal is the low cost thereof, in particular compared to the metals such as Re, Os, Ir and Pt which are otherwise customary in OLED emitters. In addition, the low toxicity of copper also supports the use thereof.

With regard to use thereof in optoelectronic components, the metal(I) complexes according to the invention are notable for a wide range of achievable emission colors. In addition, the emission quantum yield is high, especially greater than 50%. For emitter complexes with a Cu central ion, the emission decay times are astonishingly short.

In addition, the metal(I) complexes according to the invention are usable in relatively high emitter concentrations without considerable quenching effects. This means that emitter concentrations of 5% to 100% can be used in the emitter layer.

Preferably, the ligand E∩D in formulas I to IX is one of the following ligands:

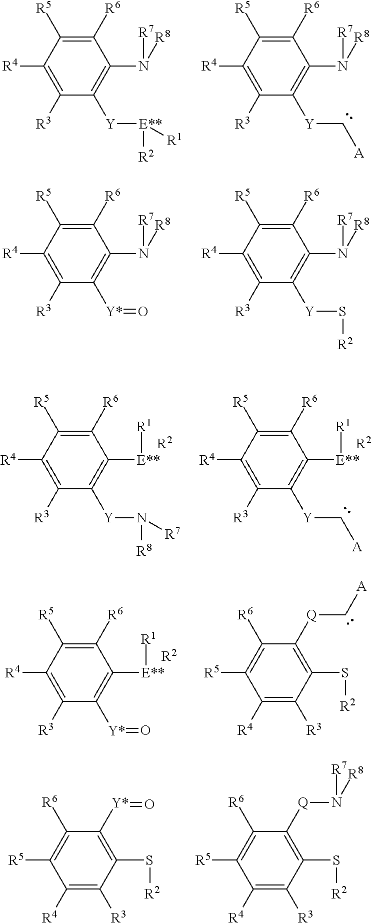

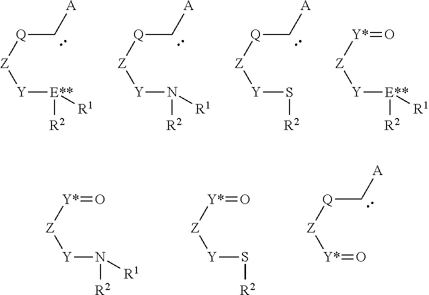

with
E**=selected from the groups consisting of P, As and Sb,
:=a carbene carbon atom,
A=independently from each other substituents selected from the group consisting of NRR′, OR, SR and PRR′ as well as alkyl (also branched or cyclic), heteroalkyl, aryl, heteroaryl, alkenyl, alkynyl groups or substituted alkyl (also branched or cyclic), heteroalkyl, aryl, heteroaryl and alkenyl groups (with substituents such as halogens or deuterium, alkyl groups (also branched or cyclic), heteroalkyl, aryl, heteroaryl groups), and further generally known donor and acceptor groups such as, for example, amines, carboxylates and their esters, and CF₃-groups, which are optionally further substituted and/or annulated;
Q, Y and Z=independently from each other substituents selected from the group consisting of NR, O, S and PR as well as alkyl (also branched or cyclic), heteroalkyl, aryl, heteroaryl, alkenyl, alkynyl groups or substituted alkyl (also branched or cyclic), heteroalkyl, aryl, heteroaryl and alkenyl groups (with substituents such as halogens or deuterium, alkyl groups (also branched or cyclic), heteroalkyl, aryl, heteroaryl groups), and further generally known donor and acceptor groups such as, for example, amines, carboxylates and their esters, and CF₃-groups, which are optionally further substituted and/or annulated;
A and Q and G and Y can optionally each be bound to each other so that an imidazilidine or an imidazole derivative is formed and/or lead with the unit Z and/or the groups R³-R⁸ also to annulated ring systems,
Y*=independently from each other selected from the group consisting of CR, N, PRR′, SR, S(O)R;
R and R′=independently from each other selected from the group consisting of hydrogen, halogen and substituents, which are bound directly or via oxygen (—OR), nitrogen (—NR₂), silicon (—SiR₃) or sulfur atoms (—SR) as well as alkyl (also branched or cyclic), heteroalkyl, aryl, heteroaryl, alkenyl, alkynyl groups or substituted alkyl (also branched or cyclic), heteroalkyl, aryl, heteroaryl and alkenyl groups (with substituents such as halogens or deuterium, alkyl groups (also branched or cyclic), heteroalkyl, aryl, heteroaryl groups), and further generally known donor and acceptor groups such as, for example, amines, carboxylates and their esters, and CF₃-groups, which are optionally further substituted and/or annulated;
R¹-R⁸ can each independently from each other be selected from the group consisting of hydrogen, halogen and substituents, which are bound directly or via oxygen (—OR), nitrogen (—NR₂), silicon (—SiR₃) or sulfur atoms (—SR) as well as alkyl (also branched or cyclic), heteroalkyl, aryl, heteroaryl, alkenyl, alkynyl groups or substituted alkyl (also branched or cyclic), heteroalkyl, aryl, heteroaryl and alkenyl groups (with substituents such as halogens or deuterium, alkyl groups (also branched or cyclic), heteroalkyl, aryl, heteroaryl groups), and further generally known donor and acceptor groups such as, for example, amines, carboxylates and their esters, and CF₃-groups, which are optionally further substituted and/or annulated. The groups R³-R⁸ can optionally also lead to annulated ring systems.

The bidentate ligand E∩D can be substituted with at least one function group FG at suitable positions. That way direct C_{FG}—C_{E∩D} bonds can be formed, wherein C_{E∩D} is a C atom of the E∩D ligand and C_{FG} is a C atom of the function group. If the bonding atom is a nitrogen atom, N_{FG}—C_{E∩D} bonds result, wherein N_{FG} stands for the nitrogen atom. On the other hand, the function group can be linked to the E∩D ligand via a bridge, wherein e.g., ether, thioether, ester, amide, methylene, silane, ethylen, ethine bridges are possible. Thereby, e.g. the following functions can result as bridges: C_{FG}—O—C_{E∩D}, C_{FG}—S—C_{E∩D}, C_{FG}—C(O)—O—C_{E∩D}, C_{FG}—C(O)—NH—C_{E∩D}, C_{FG}—CH₂—C_{E∩D}, C_{FG}—SiR′₂—C_{E∩D}C_{N*∩E}, C_{FG}—CH═CH—C_{E∩D}, C_{FG}—C≡C—C_{E∩D}, N_{FG}—CH₂—C_{E∩D}.

The methods for linking the function groups to the E∩D ligand, either directly or via a bridge, are known to a person of skill in the art (Suzuki-, Still-, Heck-, Sonogashira-, Kumuda-, Ullmann-, Buchwald-Hartwig-coupling and their variants; (thio)etherification, esterification, nucleophilic and electrophilic substitution at the sp³ carbon or aromatic compounds, etc.). The ligand (4,4′-bis(5-(hexylthio)-2,2′-bithien-5′-yl)-2,2′-bipyridine) that is described in the literature illustrates an example for the binding of an electron conducting substituent to the bpy liganden via a Stille coupling (C.-Y. Chen, M. Wang, J.-Y. Li, N. Pootrakulchote, L. Alibabaei, C.-h. Ngoc-le, J.-D. Decoppet, J.-H. Tsai, C. Gräitzel, C.-G. Wu, S. M. Zakeeruddin, M. Graitzel, ACS Nano 2009, 3, 3103).

In a particular embodiment, the group R can also be an electron conducting, hole conducting or solubility increasing substituent.

The invention also relates to a method for the production of a metal(I) complex according to the invention. This method according to the invention comprises the step of conducting the reaction of a bidentate ligand E∩D with M(I)X,

wherein
M=independently from each other selected from the group consisting of Cu and Ag,
X=independently from each other selected from the group consisting of Cl, Br, I, CN, OCN, SCN, alkynyl and N₃,
E∩D=a bidentate ligand with
E=RR′E* (if E*=N, P, As, Sb) or RE* (if E*=C*, O, S) with E*, independently from each other, selected from the group consisting of N, wherein N is no imine nitrogen atom or part of an N-heteroaromatic ring, P, C*, O, S, As and Sb with C*=a divalent carbene carbon atom and R, R′=independently from each other selected from the group consisting of hydrogen, halogen and substituents, which are bound directly or via oxygen (—OR), nitrogen (—NR₂), silicon (—SiR₃) or sulfur atoms (—SR) as well as alkyl (also branched or cyclic), heteroalkyl, aryl, heteroaryl, alkenyl, alkynyl groups or substituted alkyl (also branched or cyclic), heteroalkyl, aryl, heteroaryl and alkenyl groups (with substituents such as halogens or deuterium, alkyl groups (also branched or cyclic), heteroalkyl, aryl, heteroaryl groups), and further generally known donor and acceptor groups such as, for example, amines, carboxylates and their esters, and CF₃-groups, which are optionally further substituted and/or annulated;
D=RR′D* (if D*=N, P, As, Sb) or RD* (if D*=C*, O, S) with D* independently from each other selected from the group consisting of N (wherein N is no imine nitrogen atom or part of an N-heteroaromatic ring), P, C*, O, S, As and Sb with C*=a divalent carbene carbon atom and R, R′=independently from each other selected from the group consisting of hydrogen, halogen and substituents, which are bound directly or via oxygen (—OR), nitrogen (—NR₂), silicon (—SiR₃) or sulfur atoms (—SR) as well as alkyl (also branched or cyclic), heteroalkyl, aryl, heteroaryl, alkenyl, alkynyl groups or substituted alkyl (also branched or cyclic), heteroalkyl, aryl, heteroaryl and alkenyl groups (with substituents such as halogens or deuterium, alkyl groups (also branched or cyclic), heteroalkyl, aryl, heteroaryl groups), and further generally known donor and acceptor groups such as, for example, amines, carboxylates and their esters, and CF₃-groups, which are optionally further substituted and/or annulated;
   wherein D and E are different from each other;
“∩”=∩ is a threepart unit consiting of Q, Y and Z, which are bound to each other and are independently from each other selected from the group consisting of NR, O, S and PR as well as alkyl (also branched or cyclic), heteroalkyl, aryl, heteroaryl, alkenyl, alkynyl groups or substituted alkyl (also branched or cyclic), heteroalkyl, aryl, heteroaryl and alkenyl groups with substituents such as halogens or deuterium, alkyl groups (also branched or cyclic), heteroalkyl, aryl, heteroaryl and further generally known donor and acceptor groups such as, for example, amines, carboxylates and their esters, and CF₃ groups which are optionally further substituted and/or annulated. R is independently from each other selected from the group consisting of hydrogen, halogen and substituents, which are bound directly or via oxygen (—OR), nitrogen (—NR₂), silicon (—SiR₃) or sulfur atoms (—SR) as well as alkyl (also branched or cyclic), heteroalkyl, aryl, heteroaryl, alkenyl, alkynyl groups or substituted alkyl (also branched or cyclic), heteroalkyl, aryl, heteroaryl and alkenyl groups (with substituents such as halogens or deuterium, alkyl groups (also branched or cyclic), heteroalkyl, aryl, heteroaryl groups), and further generally known donor and acceptor groups such as, for example, amines, carboxylates and their esters, and CF₃-groups, which are optionally further substituted and/or annulated.

The substituent for increasing the solubility of the complex in organic solvents and/or improving the charge carrier transport optionally present at the ligand E∩D is described further below.

The reaction is preferably performed in dichloromethane (DCM), but also other organic solvents such as acetonitrile or tetrahydrofuran or dimethylsulfoxide or ethanol can be used. A solid can be obtained by the addition of diethyl ether or hexane or methyl-tert-butyl ether or pentane or methanol or ethanol or water to the dissolved product. The later can be performed by precipitation or diffusion or in an ultrasonic bath.

During the reaction of bidentate E∩D ligands with M(I)X (M=Ag, Cu; X=Cl, Br, I), preferably in dichloromethane (DCM), preferably at room temperature, the binuclear 2:2 complex M₂X₂(E∩D)₂ is formed, in which each metal atom is doubly coordinated by one ligand each and bridged by the two halide anions (eq. 1).

The structure of formula A is related to the known complexes of the Cu₂X₂L₂L′ and Cu₂X₂L₄. In contrast to Cu₂X₂L₄ with four monodentate ligands L (L=PR₃ or pyridine, X=Cl, Br, or I) the stability of the complex described herein is much higher due to the use of two bidentate ligands of the form E∩D (for example, visible by absorption and emission measurements of the complex in solution and as films) and in addition the rigidity of the complex is highly increased. The complex can be isolated by precipitation with Et₂O as yellow or red microcrystalline powder. Single crystals can be obtained by slow diffusion of Et₂O into the reaction solution. As soon as the complexes are present as powder or crystals they are partly sparingly soluble in common organic solvents. In particular in the case of low solubilities, the complexes were identified only by elemental analyses and X-ray structure analyses.

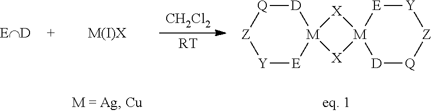

This is the general formula A shown above. The bidentate E∩D ligand can comprise at least one group R, which, each independently from each other, is selected from the group consisting of hydrogen, halogen and substituents which are bound directly or via oxygen (—OR), nitrogen (—NR₂) silicon atoms (—SiR₃) or sulfur atoms (—SR) as well as alkyl- (also branched or cyclic), heteroalkyl, aryl, heteroaryl, alkenyl, alkynyl groups or substituted alkyl (also branched or cyclic), heteroalkyl, aryl, heteroaryl and alkenyl groups (with substituents such as halogens or deuterium, alkyl groups (also branched or cyclic) heteroalkyl, aryl, heteroaryl groups), and further generally known donor and acceptor groups such as, for example, amines, carboxylates and their esters, and CF₃-groups. The substituents can also lead to annulated ring systems.

### Substituents for the Introduction of Different Functionalities

The above-mentioned substituents for the introduction of different functionalities via the different ligands (for example hole and/or electron conductors) for the provision of good charge carrier transport can be attached once or multiple times to the E∩D ligand. Identical of different function groups can be used. The function groups can be present symmetrically or asymmetrically.

### Electron Conductors

Since the electron conductor materials are exclusively aromatic compounds, a substitution is possible using one of the conventional coupling reactions. As coupling reactions, for example, Suzuki-, Still-, Heck-, Sonogashira-, Kumuda-, Ullmann-, Buchwald-Hartwig-couplings as well as their variants can be used.

An E∩D ligand substituted with an halogenide (Cl, Br, I), in particular Br, is reacted with a corresponding electron conducting material carrying a suitable leaving group. Advantageous is the performance of a Suzuki-coupling using the corresponding arylboronic acids and esters as well as the Buchwald-Hartwig-coupling for generating aryl-N-bonds. Depending on the function groups, further, common attachment reactions can also be used, e.g. via a bridge between function group FG and E∩D ligand. In the presence of —OH groups, esterification and etherification may, for example, be used, with —NH₂ groups imine and amide formation, with —COOH groups esterification. The substitution pattern of the E∩D ligand must be adapted accordingly. Methods for attaching function groups FG are known to a person of skill in the art.

As an electron transport substituent, the following groups can for example be used (the attachment position of the bond is marked with an #):

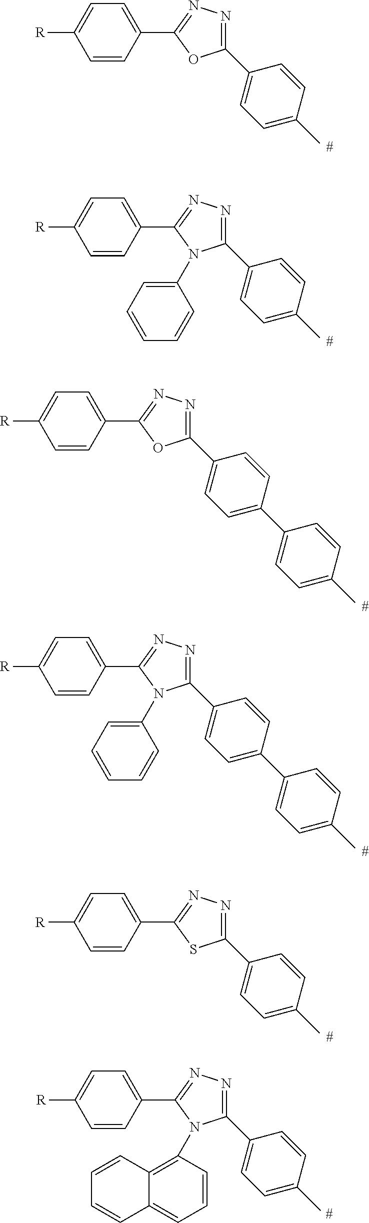

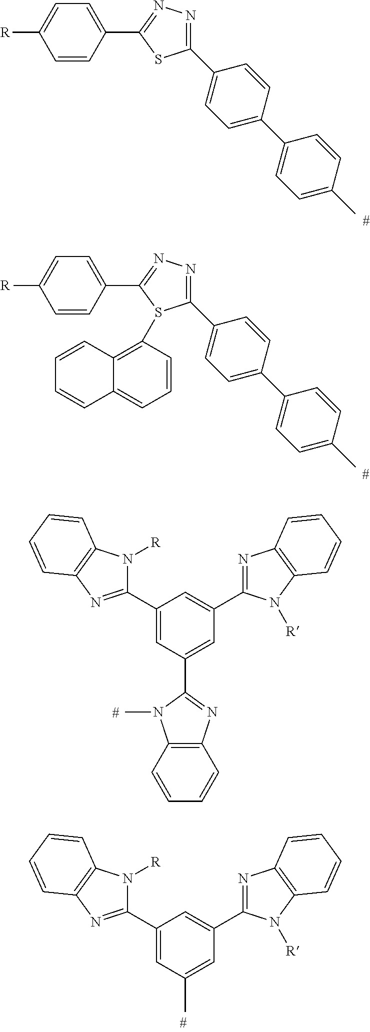

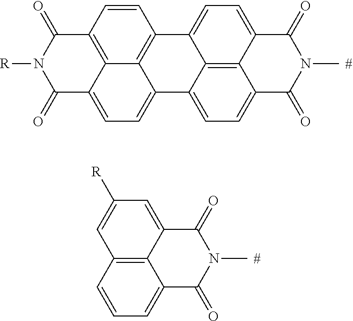

The substituents R and R′ are an alkyl group [CH₃—(CH₂)ₙ—](n=0−20) that can also be branched or substituted with halogens (F, Cl, Br, I), or an aryl group (in particular phenyl) that can be substituted with alkyl groups, halogens (F, Cl, Br, I), silane (—SiR′″₃) or ether groups —OR′″ (R′″ defined like R; the substituents used here do not necessarily correspond to the substituents R and/or R′ of formula A or of formulae I to IX). R can also be unsaturated groups such as alkenyl or alkynyl groups, which again can be substituted with alkyl groups, halogens (F, Cl, Br, I), silane (—SiR″₃) or ether groups —OR″ (R″ defined like R).

### Hole Conductors

For the hole conductor, generally the analogous applies as for the electron conductor. The attachment of the hole conductor to the E∩D ligand can most conveniently be realized through palladium-catalyzed coupling reactions; further attachments, also via a bridge, are possible as well.

As hole transport substituents, the following groups can, for example, be used (the attachments are realized at the positions marked with an #):

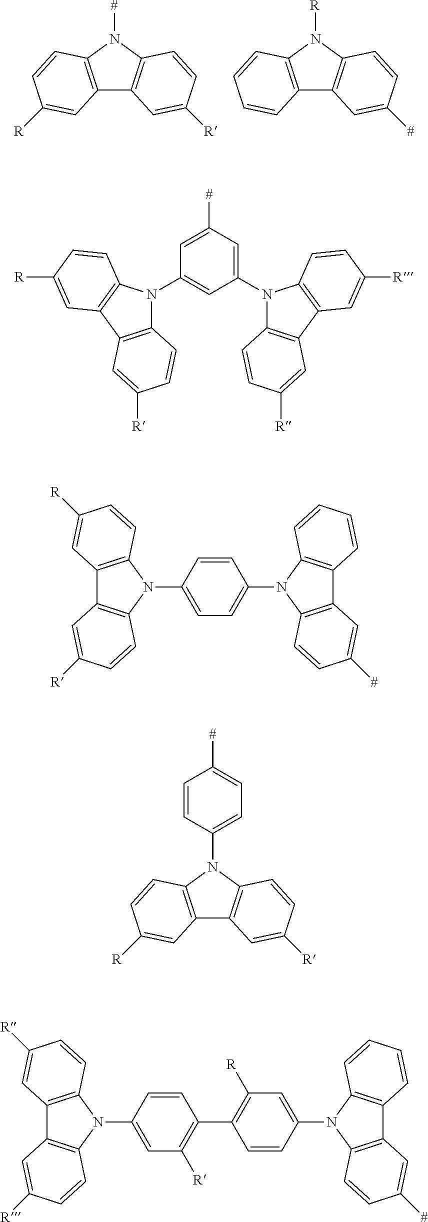

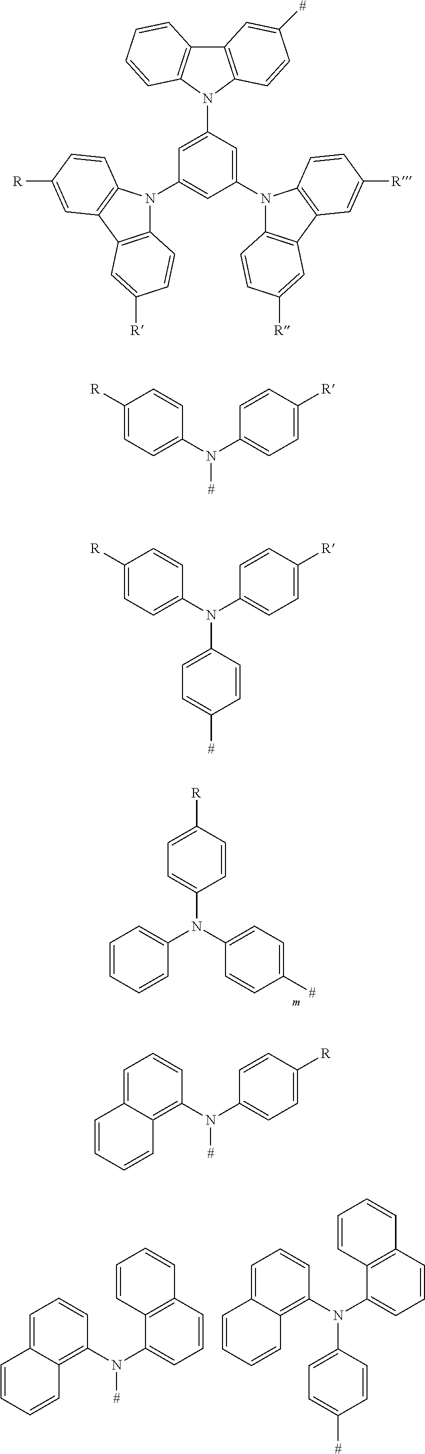

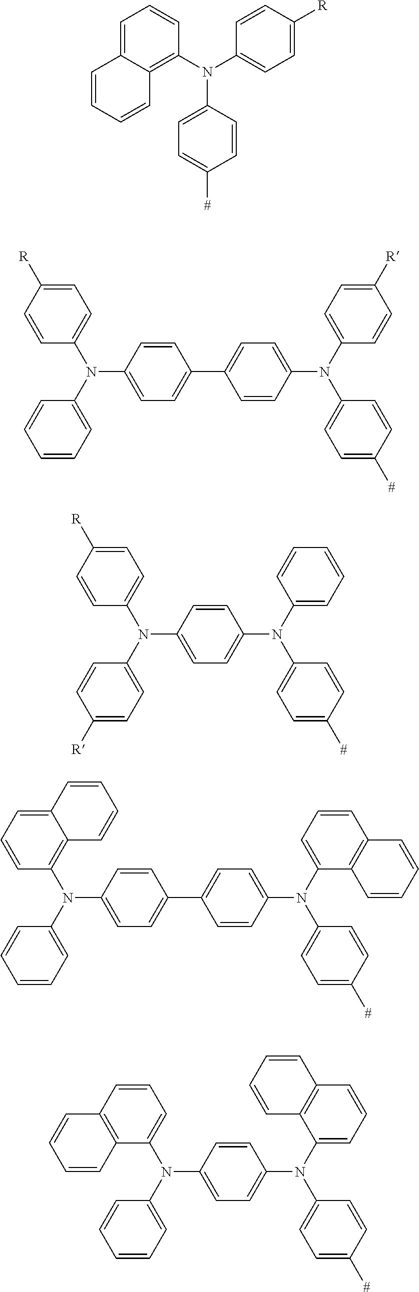

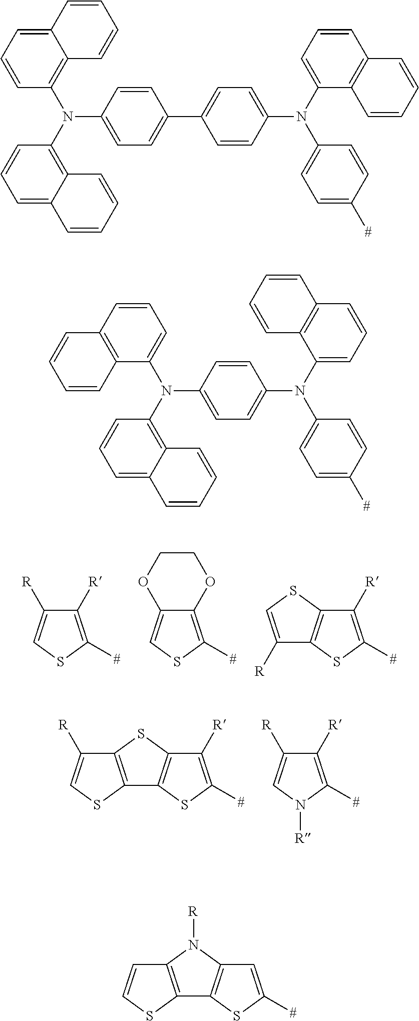

The substituents R, R″ und R′″ shown above are an alkyl group [CH₃—(CH₂)ₙ—](n=0−20) that can also be branched or substituted with halogens (F, Cl, Br, I), or an aryl group (in particular phenyl) that can be substituted with alkyl groups, halogens (F, Cl, Br, I), silane (—SiR′″₃) or ether groups —OR″″ (R″″ defined like R; the substituents used above for the conduction of holes do not necessarily correspond to the substituents R and/or R′ of formula A or of formulae I to IX). R can also be unsaturated groups such as alkenyl or alkynyl groups, which again can be substituted with alkyl groups, halogens (F, Cl, Br, I), silane (—SiR″₃) or ether groups —OR″ (R″ defined like R).

For the use of the metal(I) complexes as self-catalyzing emitter materials for realizing a cross-linking with a second reactant, functionalities can be attached in the periphery of the E∩D ligand that allow for a cross-linking with a corresponding complementary functional unit of the second reacant catalyzed by the metal(I) complex; thusn an immobilization is possible. In addition, such cross-linking provides for a stabilization and fixation of the geometrical structure of the metal complexes, whereby movement of the ligands and thus a change of structure of the excited molecules is inhibited and a decrease in efficiency due to radiationless relaxation pathways is effectively suppressed.

The copper catalyzed click reaction between a terminal or activated alkyne as first click group and an azide as a second click group is an example for a self-catalzed cross-linking reaction. Since the metal complex emitter has to carry at least two alkyne units in this embodiment, at least two of the units D, E, Q, Y, Z are preferably substituted with at least one of the above-named functional groups each for the achievement of a cross-linking, whereas the remaining units D, E, Q, Y, Z not active in the cross-linking are not substituted with at least one of the above mentioned functional groups for the achievement of cross-linking each, but can optionally be substituted with another of the above-named functional groups for the increase of solubility of the complex in organic solvents and/or for improving the charge carrier transport.

Thus, different functionalities can be introduced via the periphery of the different ligands (for example, one hole and electron transport unit each for the achievement of an optimal charge carrier transport and/or a substituent for increasing the solubility of the complex in organic solvents and/or a functional group for achieving cross-linking), whereby a very flexible adjustment and modification of the metal(I) complexes is possible.

### Solubility

When manufacturing optoelectronic devices using wet-chemical processes, it is advantageous to specifically regulate the solubility in order to avoid the complete or partial dissolution of a layer already deposited. By introducing special substituents, the solubility characteristics can be strongly influenced. Thereby it is possible to use orthogonal solvents that dissolve only the substances of the instant manufacturing step, but not the substances of the layer(s) below. For this purpose, the substituents R¹-R⁸ can be chosen such that they allow tuning of the solubilities. The following possibilities for selecting corresponding substituents are given:

### Solubility in Nonpolar Media

Nonpolar substituents R¹-R⁸ increase the solubility in nonpolar solvents and decrease the solubility in polar solvents. Nonpolar groups are, e.g. alkyl groups [CH₃—(CH₂)ₙ—](n=1−30), also branched or cyclic, substituted alkyl groups, e.g. with halogens. In particular: partially or perfluorinated alkyl groups as well as perfluorinated oligo- and polyethers, e.g. [—(CF₂)₂—O]ₙ— and (—CF₂—O)ₙ— (n=2−500). Further nonpolar groups are: ethers —OR*, thioethers —SR*, differently substituted silanes R*₃Si— (R*=alkyl or aryl), siloxanes R*₃Si—O—, oligosiloxanes R**(—R₂Si—O)ₙ— (R**=R*, n=2−20), polysiloxanes R**(—R*₂Si—O)ₙ— (n>20); oligo/polyphosphazenes R**(—R*₂P═N—)ₙ— (n=1−200).

### Solubility in Polar Media

Polar substituents R¹-R⁸ increase the solubility in polar solvents. These can be:
Alcohol groups: —OH
Carboxylic acid groups, phosphonic acid groups, sulfonic acid groups as well as their salts and esters (R*=H, alkyl, aryl, halogen; cations: alkali metals, ammonium salts):
—COOH, —P(O)(OH)₂, —P(S)(OH)₂, —S(O)(OH)₂, —COOR*, —P(O)(OR*)₂, —P(S)(OR*)₂, —S(O)(OR*)₂, —CONHR*, —P(O)(NR*₂)₂, —P(S)(NR*₂)₂, —S(O)(NR*₂)₂
Sulfoxides: —S(O)R*, —S(O)₂R*
Carbonyl groups: —C(O)R*
Amines: —NH₂, —NR*₂, —N(CH₂CH₂OH)₂,
Hydroxylamines=NOR*
Oligoesters, —O(CH₂O—)ₙ, —O(CH₂CH₂O—)ₙ (n=2−200)
Positively charged substituents: e.g. ammonium salts —N⁺R*₃X⁻, phosphonium salts —P⁺R*₃X⁻
Negatively charged substituents: e.g. borates —(BR*₃)⁻, aluminates —(AlR*₃)⁻ (the anion can be an alkali metal or ammonium ion).

The preparation method can optionally include the step of substituting at least one ligand E∩D with at least one substituent listed above to increase the solubility in an organic solvent, wherein the substituent in one embodiment of the invention can be selected from the group consisting of:
long-chain, branched or unbranched or cyclic alkyl chains of length C1 to C30,
long-chain, branched or unbranched or cyclic alkoxy chains of length C1 to C30,
branched or unbranched or cyclic perfluoroalkyl chains of length C1 to C30, and
short-chain polyethers.

The preparation method can optionally comprise the step that at least one ligand E∩D is substituted with at least one of the above-named functional groups for improving charge carrier transport, wherein the functional group at a ligand E∩D can be identical or different to the functional group at the other ligand, preferably different, wherein the substituent can be selected in one embodiment of the invention from the group consisting of electron conductors and hole conductors.

In one aspect, the invention pertains to metal(I) complexes, which can be synthesized by the synthesis method described herein.

According to the invention, the metal(I) complexes of the formula A can be applied as emitter materials in an emitter layer of a light-emitting optoelectronic component.

According to the invention, the metal(I) complexes of formula A can also be applied as absorber materials in an absorber layer of an optoelectronic component.

The term “optoelectronic components” refers in particular to:
organic light emitting components (organic light emitting diodes, OLEDs),
light emitting electrochemical cells (LECs, LEECs),
OLED-sensors, in particular in gas and vapor sensors, which are not hermetically sealed from the outside,
organic solar cells (OSCs, organic photovoltaics, OPVs),
organic field-effect transistors, and
organic lasers.

In one embodiment of the invention, the ratio of the metal(I) complex in the emitter layer or absorber layer in such an optoelectronic component is 100%. In an alternative embodiment, the ratio of the metal(I) complex in the emitter layer or absorber layer is 1% to 99%.

Preferably, the concentration of the metal(I) complex as emitter in optical light emitting components, particularly in OLEDs, is between 5% and 80%.

The present invention also pertains to optoelectronic components which comprise a metal(I) complex as described herein. The optoelectronic component can be implemented as an organic light emitting component, an organic diode, an organic solar cell, an organic transistor, as an organic light emitting diode, a light emitting electrochemical cell, an organic field-effect transistor and as an organic laser.

Furthermore, the invention relates to a method for the preparation of an optoelectronic device wherein a metal(I) complex according to the invention of the form described herein is used. In this method, in particular a metal(I) complex according to the invention is applied onto a support. The application can be conducted wet-chemically, by means of colloidal suspension or by means of sublimation, in particular wet-chemically. The method can comprise the following steps:

Depositing a first emitter complex dissolved in a first solvent onto a carrier, and depositing a second emitter complex dissolved in a second solvent onto the carrier;
wherein the first emitter complex is not soluble in the second solvent, and the second emitter complex is not soluble in the first solvent; and wherein the first emitter complex and/or the second emitter complex is a metal(I) complex according to the invention. The method can further comprise the following step: Depositing a third emitter complex dissolved in a first solvent or in a third solvent onto the carrier, wherein the third complex is a metal(I) complex according to the invention. The first and the second solvent are not identical.

The present invention also relates to a method for altering the emission and/or absorption properties of an electronic component. According to the method, a metal(I) complex according to the invention is introduced into a matrix material for conducting electrons or holes into an optoelectronic component.

The present invention also relates to the use of a metal(I) complex according to the invention, particularly in an optoelectronic component, for conversion of UV radiation or of blue light to visible light, especially to green (490-575 nm), yellow (575-585 nm), orange (585-650 nm) or red light (650-750 nm) (down-conversion).

In a preferred embodiment, the optoelectronic device is a white-light OLED, wherein the first emitter complex is a red-light emitter, the second emitter complex is a green-light emitter and the third emitter complex is a blue-light emitter. The first, the second and/or the third emitter complex is preferably a metal(I) complex according to the invention.

Since the metal(I) complexes according to the invention with unsubstituted E∩D ligands are in part sparingly soluble in some organic solvents, they may not be processable directly from solution. In the case of solvents that are themselves good ligands (acetonitrile, pyridine), a certain solubility exists, but a change in the structure of the complexes or displacement of the phosphine, arsine or antimony ligands under these conditions cannot be ruled out. It is therefore unclear whether the substances, in the event of deposition onto the substrate, will crystallize as M₂X₂(E∩D)₂, or will be present molecularly in this form in the matrix. For this reason, the substances should be produced in a size suitable for use in optoelectronic components or be comminuted thereto (<20 nm to 30 nm, nanoparticles), or be made soluble by means of suitable substituents.

The metal(I) complexes according to the invention are preferably processed from solution, since the high molecular weight complicates deposition from vacuum by sublimation. Accordingly, the photoactive layers are preferably produced from solution by spin-coating or slot-casting processes, or by any printing process such as screenprinting, flexographic printing, offset printing or inkjet printing.

The unsubstituted metal(I) complexes described here (definition further below, see examples) are, however, sparingly soluble in the standard organic solvents, except in dichloromethane, which should not be used for OLED component production in a glovebox. Application as a colloidal suspension is viable in many cases (see below), but industrial processing of the emitter materials in dissolved form is usually simpler in technical terms. It is therefore a further object of this invention to chemically alter the emitters such that they are soluble. Suitable solvents for the OLED component production are, besides alcohols, ethers, alkanes as well as halogenated aromatic and aliphatic hydrocarbons and alkylated aromatic hydrocarbons, especially toluene, chlorobenzene, dichlorobenzene, mesitylene, xylene, tetrahydrofuran, phenetole, and propiophenone.

In order to improve the solubility of the metal(I) complexes according to the invention in organic solvents, at least one of the E∩D structures is preferably substituted by at least one of the above mentioned substituent. The substituent can be selected from the group consisting of:
long-chain, branched or unbranched or cyclic alkyl chains with a length of C1 to C30, preferably with a length of C3 to C20, more preferably with a length of C5 to C15,
long-chain, branched or unbranched or cyclic alkoxy chains with a length of C1 to C30, preferably with a length of C3 to C20, more preferably with a length of C5 to C15,
branched or unbranched or cyclic perfluoroalkyl chains with a length of C1 to C30, preferably with a length of C3 to C20, more preferably with a length of C5 to C15, and
short-chain polyethers, for example polymers of the (—OCH₂CH₂O—)ₙ form with n<500. Examples thereof are polyethylene glycols (PEGs), which can be used as chemically inert, water-soluble and nontoxic polymers with a chain length of 3-50 repeat units.

In a preferred embodiment of the invention, the alkyl chains or alkoxy chains or perfluoroalkyl chains are modified with polar groups, for example with alcohols, aldehydes, acetals, amines, amidines, carboxylic acids, carboxylic esters, carboxylic acid amides, imides, carboxylic acid halides, carboxylic anhydrides, ethers, halogens, hydroxamic acids, hydrazines, hydrazones, hydroxylamines, lactones, lactams, nitriles, isocyanides, isocyanates, isothiocyanates, oximes, nitrosoaryls, nitroalkyls, nitroaryls, phenols, phosphoric esters and/or phosphonic acids, thiols, thioethers, thioaldehydes, thioketones, thioacetals, thiocarboxylic acids, thioesters, dithio acids, dithio esters, sulfoxides, sulfones, sulfonic acid, sulfonic esters, sulfinic acids, sulfinic esters, sulfenic acid, sulfenic esters, thiosulfinic acid, thiosulfinic esters, thiosulfonic acid, thiosulfonic esters, sulfonamides, thiosulfonamides, sulfinamides, sulfenamides, sulfates, thiosulfates, sultones, sultams, trialkylsilyl and triarylsilyl groups, and also trialkoxysilyl groups which result in a further increase in solubility.

A very marked increase in solubility is achieved from at least one C3 unit, branched or unbranched or cyclic.

In order to improve the charge carrier transport to the metal(I) complexes according to the invention at leat one of the structures E∩D is preferably substituted with at least one of the above-listed functional groups for the improvement of the charge carrier transport, wherein the functional group at a ligand E∩D can be identical or different to the functional group at the other ligand, preferably different. The substituent can be selected from the group consisting of electron conductor and hole conductor.

The substituents of the structures E∩D of the metal(I) complexes can be arranged at any position of the structure.

A further aspect of the invention relates to the alteration of the emission colors of the metal(I) complexes by means of electron-donating or -withdrawing substituents, or by means of fused N-heteroaromatics. The terms electron-donating and electron-withdrawing are known to those skilled in the art.

Examples of electron-donating substituents are especially:

-alkyl, -phenyl, —CO₂(−), —O(−), —NH-alkyl group, —N-(alkyl group)₂, —NH₂, —OH, —O-alkyl group, —NH(CO)-alkyl group, —O(CO)-alkyl group, —O(CO)-aryl group, —O(CO)-phenyl group, —(CH)═C-(alkyl group)₂, —S-alkyl group.

Examples of electron-withdrawing substituents are especially:

-halogen, —(CO)H, —(CO)-alkyl group, —(CO)O-alkyl group, —(CO)OH, —(CO)halide, —CF₃, —CN, —SO₃H, —NH₃(+), —N(alkyl group)₃(+), —NO₂.

Advantageously, the electron-donating and -withdrawing substituents are as far as possible away from the coordination site of the ligand.

By choosing suitable substitution within the basic structure of the E∩D ligand, a very broad range of emission color can be reached.

The change of emission color of the metal(I) complexes described herein can also be effected by further heteroatoms such as N, O, S as well as by fused aromatics.

The use of fused aromatics like, for example, naphthyl, anthracenyl, phenanthrenyl etc. allows for color shifts, for example into the yellow to deep-red spectral area. The increase of the solubility of metal(I) complexes with fused aromatics can also be carried out by substitution(s) with the substituents described above, long-chain (branched, unbranched or cyclic) alkyl chains with a length of C1 to C30, preferably with a length of C3 to C20, particularly preferably with a length of C5 to C15, long-chain, branched or unbranched or cyclic alkoxy chains with a length of C1 to C30, preferably with a length of C3 to C20, particularly preferably with a length of C5 to C15, long-chain, branched or unbranched or cyclic perfluoroalkyl chains with a length of C1 to C30, preferably with a length of C3 to C20, particularly preferably with a length of C5 to C15, short-chain polyethers (chain length: 3-50 repeat units).

In a preferred embodiment, the metal(I) complex of the invention has at least one substituent to increase solubility in an organic solvent and/or at least one electron-donating and/or at least one electron-withdrawing substituent. It is also possible that a substituent which improves solubility is simultaneously either an electron-donating or -withdrawing substituent. One example of such a substituent is a dialkylated amine with electron-donating effect via the nitrogen atom and solubility-increasing effect through the long-chain alkyl groups.

By means of a modular synthesis strategy in which the individual units for preparation of these ligands are combined with one another in a matrix, the introduction of linear and branched and cyclic alkyl chains, alkoxy chains or perfluoroalkyl chains of different lengths at different positions in the molecules is possible. Preference is given to substitutions which are far away from the coordination site of the ligand E∩D.

For the production of the above-mentioned nanoparticles smaller than 30 nm, several techniques can be employed:^{[xxii]}

Bottom-up processes for the synthesis of nanoparticles:
Rapid injection of the reaction solution into a large excess of a suitable precipitant (e.g. pentane, diethyl ether).^{[xxiii]}
Fine spraying of the reaction solution in a vacuum chamber, possibly at elevated temperature (spray drying). This vaporizes the solvent, leaving the complex in finely distributed form.
In a freeze-drying process, the droplets of the reaction solution are dispersed in a coolant (e.g. liquid nitrogen), which freezes the material. Subsequently, it is dried in the solid state.
Codeposition of the complexes and of the matrix material on the substrate directly from the reaction solution.
Synthesis in an ultrasonic bath.
   Top-down processes for comminution of the substances:
Comminution by means of high-energy ball mills.^{[xxiv]}
Comminution by means of high-intensity ultrasound.

Isolation of the particle size required can be achieved by filtration with suitable filters or by centrifugation.

In order to achieve homogeneous distribution of the nanoparticles in the matrix (for example of the matrix material used in the emitter layer), a suspension is prepared in a solvent in which the matrix material dissolves. Any of the customary processes (for example spin-coating, inkjet printing, etc.) can be used to apply the matrix material and the nanoparticles to a substrate with this suspension. In order to avoid aggregation of the nanoparticles, stabilization of the particles by means of surface-active substances may be necessary under some circumstances. However, these should be selected such that the complexes are not dissolved. Homogeneous distribution can also be achieved by the abovementioned co-deposition of the complexes together with the matrix material directly from the reaction solution.

Since the substances described possess a high emission quantum yield even as solids, they can also be deposited directly on the substrate as a thin layer (100% emitter layer) proceeding from the reaction solution.

### FIGURES

FIG. 1: Basic structure of an OLED. The figure is not drawn to scale.

FIG. 2: Solid-state structure of 1b.

FIG. 3: Emission spectra of the solid, crystalline samples of 1a-1c (excitation at 350 nm).

FIG. 4: Calculated frontier orbitals of the ground state of 1b.

FIG. 5: Emission spectra of the solid, crystalline samples of 2a-2d (excitation at 350 nm).

FIG. 6: Emission spectra of the solid, crystalline samples of 9a-9c (excitation at 350 nm).

FIG. 7: Emission spectrum of a solid, crystalline sample of 9c and in comparison of a film of 9c (neat solved in toluene) (excitation at 350 nm).

FIG. 8: Electroluminescence spectrum of 9a in an OLED (ITO/PEDOT:PSS/HTL/emitter 9a in matrix/ETL/cathode).

FIG. 9: Current-voltage characteristic and brightness of 9a in an OLED (ITO/PEDOT:PSS/HTL/emitter 9a in matrix/ETL/cathode).

FIG. 10: Emission spectrum of the solid, crystalline samples of 10c (excitation at 350 nm).

FIG. 11: Emission spectra of the solid, crystalline samples of 11a-11c (excitation at 350 nm).

FIG. 12: Emission spectrum of the solid, crystalline samples of 12c (excitation at 350 nm).

FIG. 13: Emission spectrum of the solid, crystalline samples of 13c (excitation at 350 nm).

FIG. 14: Emission spectra of the solid, crystalline samples of 14a-14c (excitation at 350 nm).

FIG. 15: Emission spectrum of the solid, crystalline samples of 15c (excitation at 350 nm).

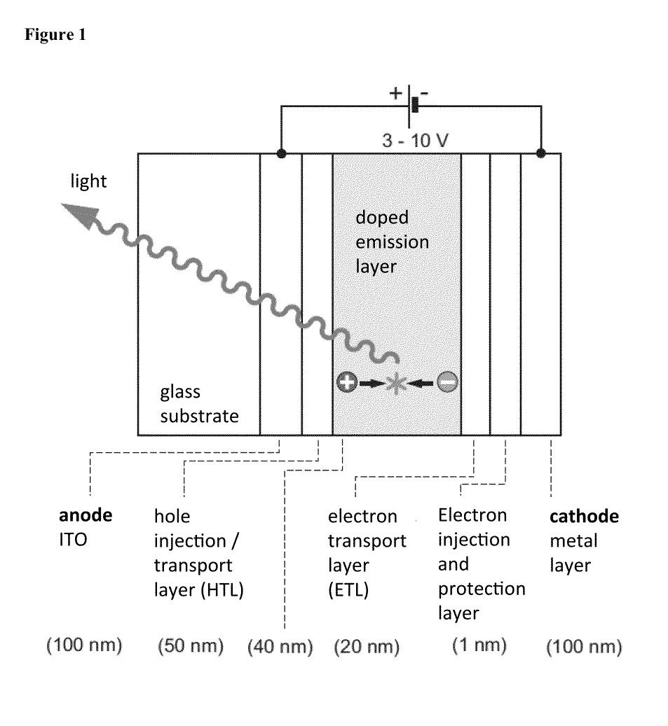

### EXAMPLES

In the examples shown here, the bidentate ligand E∩D of the general formula A is an amine phosphine ligand (with E=PPh₂ and D=NMe₂ or E=PPh₂ and D=N(CH₂)₄), an amine thioether ligand (with E=SPh and D=NMe₂), a phosphine carbene ligand (with E=PPh₂ and D=C*), an amine carbene ligand (with E=NMe₂ and D=C*) or a thioether carbene ligand (with E=SPh and D=C*).

The dotted double bond in the carbene ligand means that either only a single bond is present and thus an imidazolidine carbene is used, or that alternatively a double bond is present and thus an imidazole carbene is used.

### Examples for Complexes of the M₂X₂(E∩D)₂ Form

I. E∩D=Ph₂PMe₂NBenzyl, X=Cl, Br, I: Cu₂Cl₂(Ph₂PMe₂NBenzyl)₂ (1a), Cu₂Br₂(Ph₂PMe₂NBenzyl)₂ (1b), Cu₂I₂(Ph₂PMe₂NBenzyl)₂ (1c)

The compounds 1a-c are yellow, fine-crystalline solids.

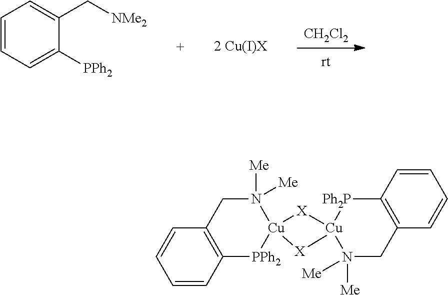

Characterization:

1a: ¹H-NMR (CDCl₃): δ 7.75-7.02 (m, Ar—H, 28H), 3.41 (bs, CH₂, 4H), 2.33 (bs, NMe₂, 12H) ppm.

³¹P-NMR (CDCl₃): −21 ppm.

EA C₄₂H₄₄Cu₂Cl₂N₂P₂ (834.09): calc.: C, 60.29; H, 5.30; N, 3.35.

found: C, 60.10; H, 5.51, N, 3.12.

1b: ¹H-NMR (CDCl₃): δ 7.66-7.20 (m, Ar—H, 28H), 3.47 (bs, CH₂, 4H), 2.42 (bs, NMe₂, 12H) ppm.

³¹P-NMR (CDCl₃): −20 ppm.

IR (ATR): 3045 (vw), 2998 (vw), 2825 (vw), 1585 (vw), 1461 (w), 1434 (w), 1370 (w), 1309 (vw), 1242 (vw), 1173 (vw), 1128 (vw), 1096 (s), 1035 (w), 1000 (s), 880 (vw), 836 (s), 752 (vs), 744 (vs), 694 (vs), 621 (w), 518 (vs), 489 (vs), 451 (m), 436 (s) cm⁻¹ FAB-MS 926 [M]⁺, 845 [Cu₂BrL_{2]}⁺, 526 [Cu₂BrL]⁺, 463 [CuBrL]⁺, 383 [CuL]⁺.

EA C₄₂H₄₄Cu₂Br₂N₂P₂ (921.99): calc.: C, 54.50; H, 4.79; N, 3.03.

found: C, 54.30; H, 4.85; N, 2.82.

1c: ¹H-NMR (CDCl₃): δ 7.72-7.10 (m, Ar—H, 28H), 3.45 (bs, CH₂, 4H), 2.40 (bs, NMe₂, 12H) ppm.

³¹P-NMR (CDCl₃): −18 ppm.

IR (ATR): 2823 (vw), 1568 (vw), 1476 (w), 1454 (w), 1432 (m), 1359 (vw), 1305 (vw), 1203 (vw), 1162 (vw), 1125 (vw), 1093 (m), 997 (m), 984 (m), 886 (w), 836 (s), 761 (vw), 744 (vs), 692 (vs), 619 (vw), 530 (m), 509 (vs), 490 (vs), 454 (vs), 426 (vs) cm⁻¹ FAB-MS 1022 [Cu₂I₂L_{2]}⁺, 892 [Cu₂IL]⁺, 505 [CuIL]⁺.

EA C₄₂H₄₄Cu₂I₂N₂P₂ (1017.97): calc.: C, 49.47; H, 4.35; N, 2.75.

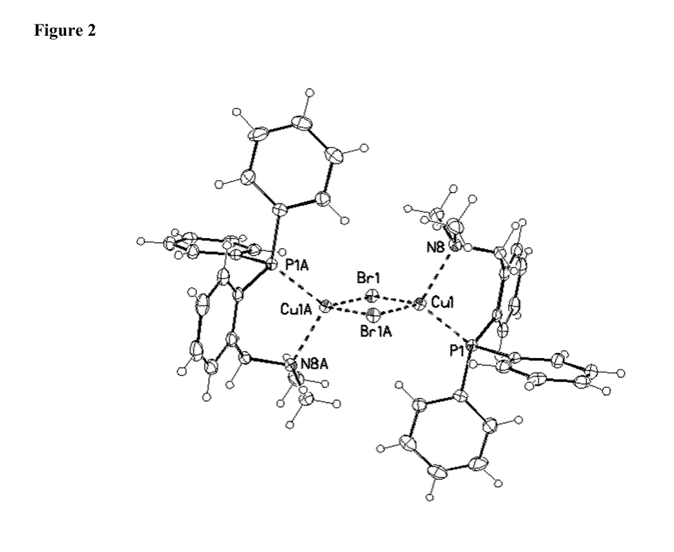

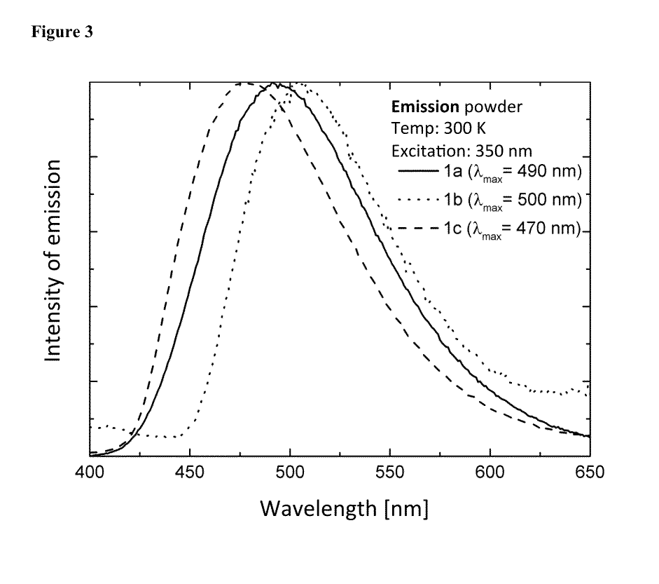

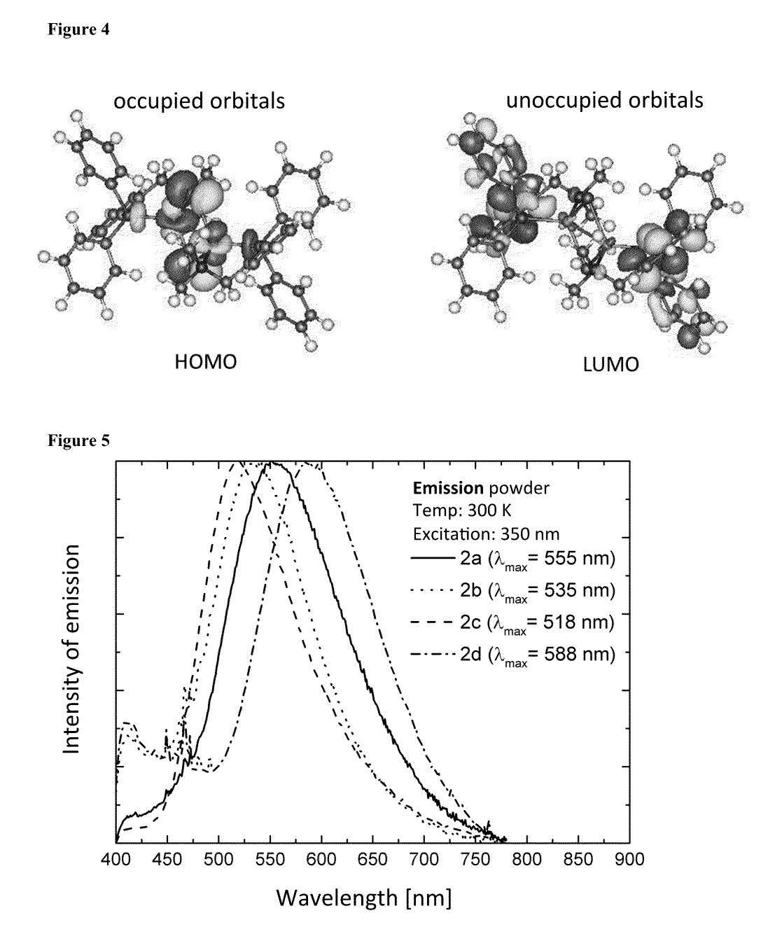

found: C, 49.36; H, 4.40; N, 2.53.
The crystal structure is shown in FIG. 2 (1b).
The emission spectra of 1a-1c are shown in FIG. 3.
The calculated frontier orbitals of the ground state of 1b are shown in FIG. 4.
   II. E∩D=Ph₂PMe₂NNaphtyl, X=Cl, Br, I, CN: Cu₂Cl₂(Ph₂PMe₂NNaphtyl)₂ (2a), Cu₂Br₂(Ph₂PMe₂NBenzyl)₂ (2b), Cu₂I₂(Ph₂PMe₂NBenzyl)₂ (2c), Cu₂CN₂(Ph₂PMe₂NBenzyl)₂ (2d),

The compounds 2a-d are white, fine-crystalline solids.

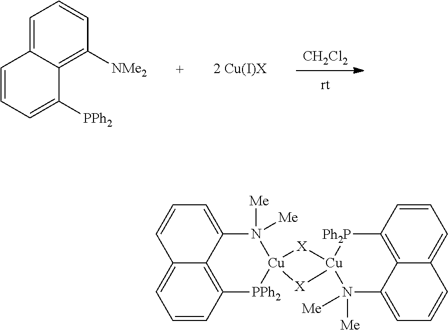

Characterization:

Elemental analysis:

2a: Elemental formula: C₄₈H₄₄Cl₂Cu₂N₂P₂.½ H₂O

calc.: C, 62.20; H, 5.00; N, 3.02.

found: C, 62.02; H, 4.71; N, 2.87.

2b: Elemental formula: C₄₈H₄₄Br₂Cu₂N₂P₂

calc.: C, 57.78; H, 4.45; N, 2.81.

found: C, 57.61; H, 4.36; N, 2.64.

2c: Elemental formula: C₄₈H₄₄Cl₂Cu₂N₂P₂

calc.: C, 52.81; H, 4.06; N, 2.57.

found: C, 52.60; H, 3.93; N, 2.34.

2d: Elemental formula: C₅₀H₄₄Cu₂N₄P₂.½ H₂O

calc.: C, 66.14; H, 5.11; N, 6.17.

found: C, 65.72; H, 4.76; N, 6.57.
The emission spectra of 2a-2d are shown in FIG. 5.
   III. E∩D=Ph₂POMe₂NPhenyl, X=Cl, Br, I: Cu₂Cl₂(Ph₂POMe₂NPhenyl)₂ (3a), Cu₂Br₂(Ph₂POMe₂NPhenyl)₂ (3b), Cu₂I₂(Ph₂POMe₂NPhenyl)₂ (3c)

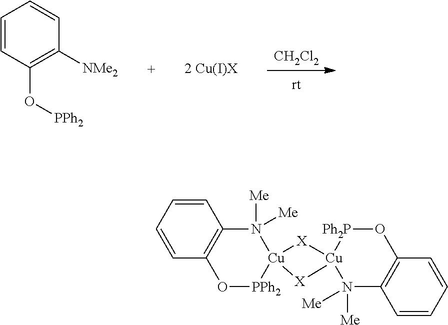

IV. E∩D=PhSMe₂NBenzyl, X=Cl, Br, I: Cu₂Cl₂(PhSMe₂NBenzyl)₂ (4a), Cu₂Br₂(PhSMe₂NBenzyl)₂ (4b), Cu₂I₂(PhSMe₂NBenzyl)₂ (4c)

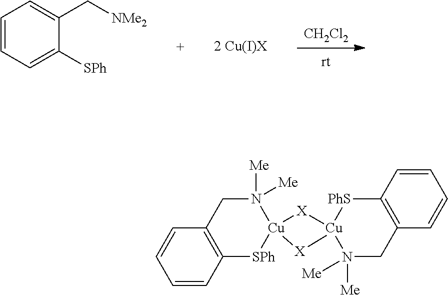

V. E∩D=Me₂NPhSBenzyl, X=Cl, Br, I: Cu₂Cl₂(Me₂NPhSBenzyl)₂ (5a), Cu₂Br₂(Me₂NPhSBenzyl)₂ (5b), Cu₂I₂(Me₂NPhSBenzyl)₂ (5c)

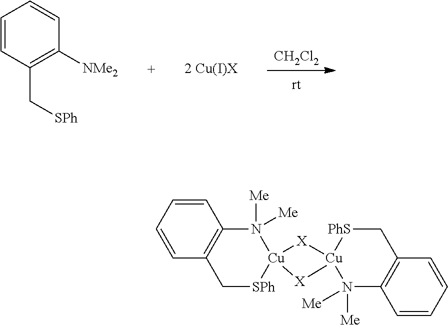

VI. E∩D=Ph₂PNHCPhenyl, X=Cl, Br, I: Cu₂Cl₂(Ph₂PNHCPheny)₂ (6a), Cu₂Br₂(Ph₂PNHCPheny)₂ (6b), Cu₂I₂(Ph₂PNHCPheny)₂ (6c)

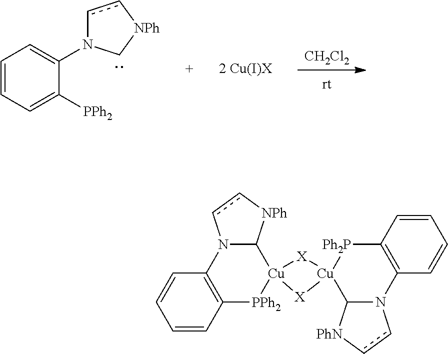

The following reaction is preferred:

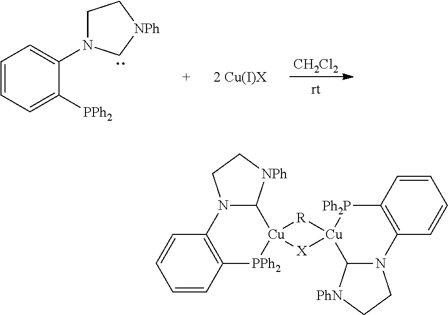

VII. E∩D=Me₂NNHCPhenyl, X=Cl, Br, I: Cu₂Cl₂(Me₂NNHCPhenyl)₂ (7a), Cu₂Br₂(Me₂NNHCPhenyl)₂ (7b), Cu₂I₂(Me₂NNHCPhenyl)₂ (7c)

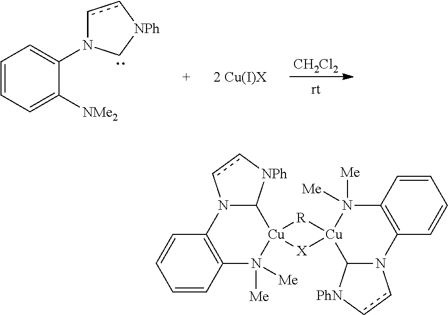

The following reaction is preferred:

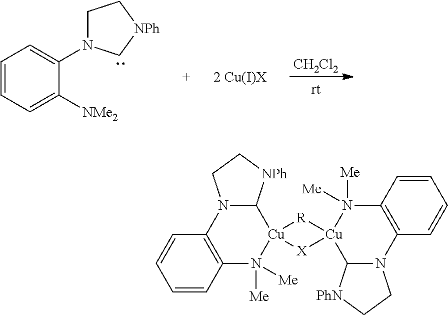

VIII. E∩D=PhSNHCPhenyl, X=Cl, Br, I: Cu₂Cl₂(PhSNHCPhenyl)₂ (8a), Cu₂Br₂(PhSNHCPhenyl)₂ (8b), Cu₂I₂(PhSNHCPhenyl)₂ (8c)

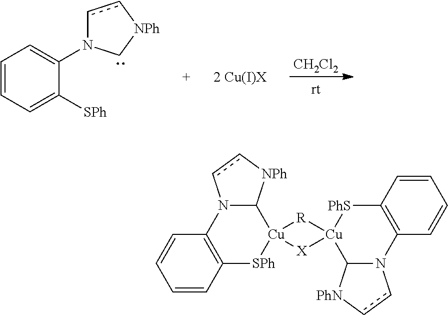

The following reaction is preferred:

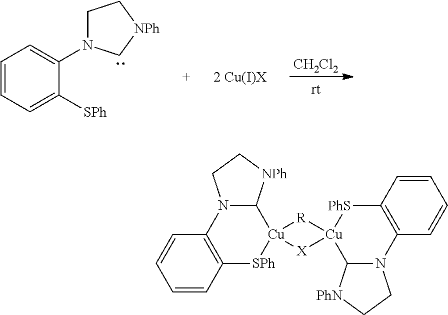

IX. E∩D=Ph₂P(CH₂)₄NBenzyl, X=Cl, Br, I: Cu₂Cl₂(Ph₂P(CH₂)₄NBenzyl)₂ (9a), Cu₂Br₂(Ph₂P(CH₂)₄NBenzyl)₂ (9b), Cu₂I₂(Ph₂P(CH₂)₄NBenzyl)₂ (9c)

The compounds 9a-c are fine-crystalline solids.

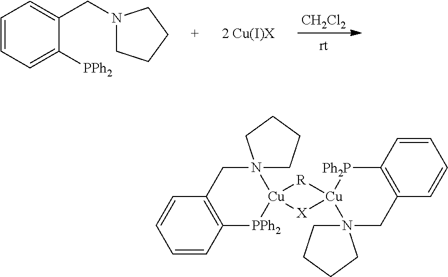

The available compounds were characterized by 1H and 31P NMR spectroscopy and their structure was determined by comparison to the related structures 1a-c, which were confirmed by X-ray diffraction.

9a: ¹H-NMR (CDCl₃): 1.65 (bs, 4H, NCH₂CH₂), 2.45 (bs, 4H, NCH₂CH₂), 3.40 (bs, 2H, ArCH₂), 7.00-8.00 (m, 14H, Ar—H) ppm.

³¹P-NMR (CDCl₃): −22 ppm.

9b: ¹H-NMR (CDCl₃): 1.72 (bs, 4H, NCH₂CH₂), 2.53 (bs, 4H, NCH₂CH₂), 3.50 (bs, 2H, ArCH₂), 7.00-8.00 (m, 14H, Ar—H) ppm.

³¹P-NMR (CDCl₃): −20 ppm.

9c: ¹H-NMR (CDCl₃): 1.70 (bs, 4H, NCH₂CH₂), 2.52 (bs, 4H, NCH₂CH₂), 3.46 (bs, 2H, ArCH₂), 7.00-8.00 (m, 14H, Ar—H) ppm.

³¹P-NMR (CDCl₃): −16 ppm.

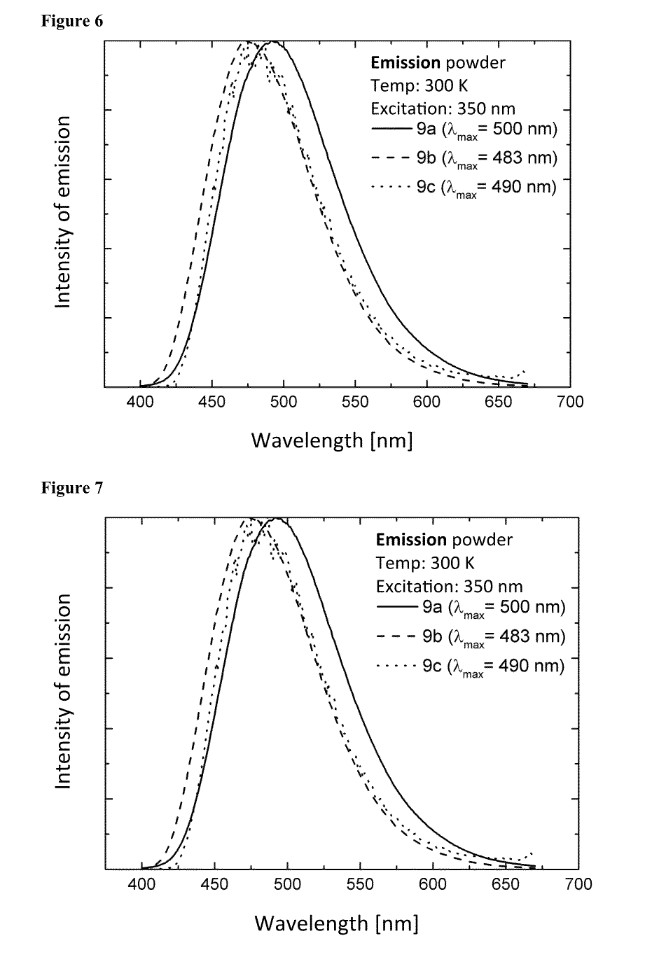

The emission spectra of 9a-9c are shown in FIG. 6. The emission spectra of 9c in comparison as powder and as film (pure in toluene) are shown in FIG. 7

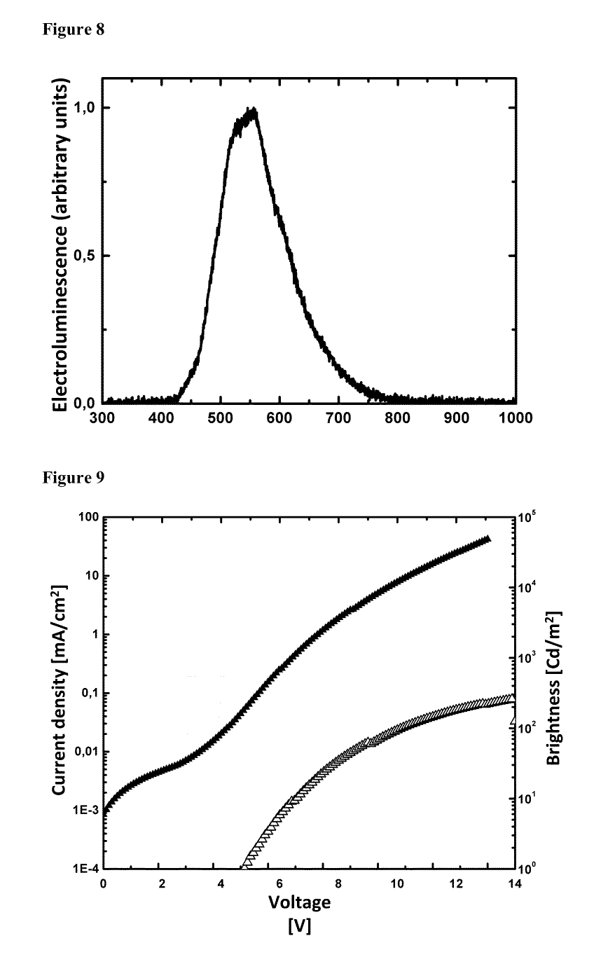

The electroluminescence spectrum of 9a is shown in FIG. 8.

The current-voltage characteristic as well as the brightness of 9a is shown in FIG. 9.

X. E∩D=Ph₂P(CH₂)₄NCH₃Benzyl, X=Cl, Br, I: Cu₂Cl₂(Ph₂P(CH₂)₄NCH₃Benzyl)₂ (10a), Cu₂Br₂(Ph₂P(CH₂)₄NCH₃Benzyl)₂ (10b), Cu₂I₂(Ph₂P(CH₂)₄NCH₃Benzyl)₂ (10c)

The compounds 10a-c are fine-crystalline solids.

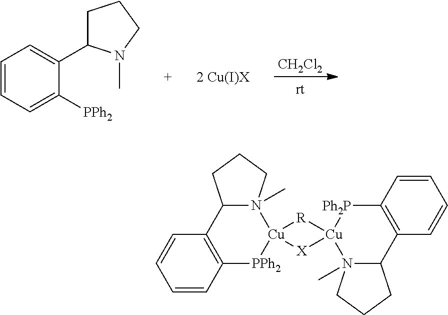

The available compound with X=I was characterized by 1H and 31P NMR spectroscopy and its structure was determined by comparison to the related structures 1a-c, which were confirmed by X-ray diffraction.

10c: ¹H-NMR (CDCl₃): δ=7.55-7.52 (m, 2H), 7.45-7.28 (m, 11H), 7.11-7.08 (t, 1H), 3.78 (s, 1H), 3.53 (s, 1H), 2.43 (s, 34H), 2.40 (s, 1H), 2.05 (m, 1H), 1.85 (m, 1H), 1.69 (m, 2H) ppm.

³¹P-NMR (CDCl₃): −18 ppm.

The emission spectrum of 10c is shown in FIG. 10.

XI. E∩D=Ph₂PPiperidineNBenzyl, X=Cl, Br, I: Cu₂Cl₂(Ph₂PPiperidineNBenzyl)₂ (11a), Cu₂Br₂(Ph₂PPiperidineNBenzyl)₂ (11b), Cu₂I₂(Ph₂PPiperidineNBenzyl)₂ (11c)

The compounds 11a-c are fine-crystalline solids.

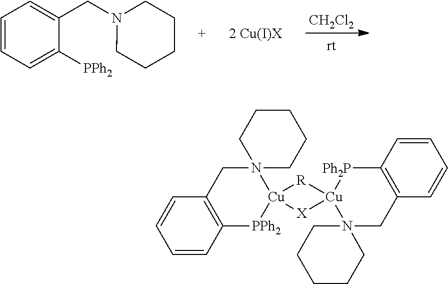

The available compounds with X=Cl and X=Br were characterized by 1H and 31P NMR spectroscopy and their structure was determined by comparison to the related structures 1a-c, which were confirmed by X-ray diffraction.

11a: ¹H-NMR (CDCl₃, 500 MHz) δ=7.56-7.50 (m, 4H), 7.44-7.33 (m, 6H), 7.32-7.30 (m, 2H), 7.21 (d, 1H), 6.85 (d, 1H), 3.56 (s, 2H), 2.58 (s, 4H), 1.95 (s, 4H), 1.34 (s, 2H) ppm.

³¹P-NMR (CDCl₃): −19 ppm.

11b: ¹H-NMR (CDCl₃, 500 MHz) δ=7.57-7.54 (m, 4H), 7.44-7.36 (m, 7H), 7.30-7.25 (m, 2H), 6.98-6-92 (m, 1H), 3.57 (s, 2H), 2.60 (s, 4H), 2.00 (s, 4H), 1.44 (s, 2H) ppm.

³¹P-NMR (CDCl₃): −20 ppm.

11c: EA: calc.: C, 50.06; H, 4.38; N, 2.54.

found: C, 49.92; H, 4.23; N, 2.50.

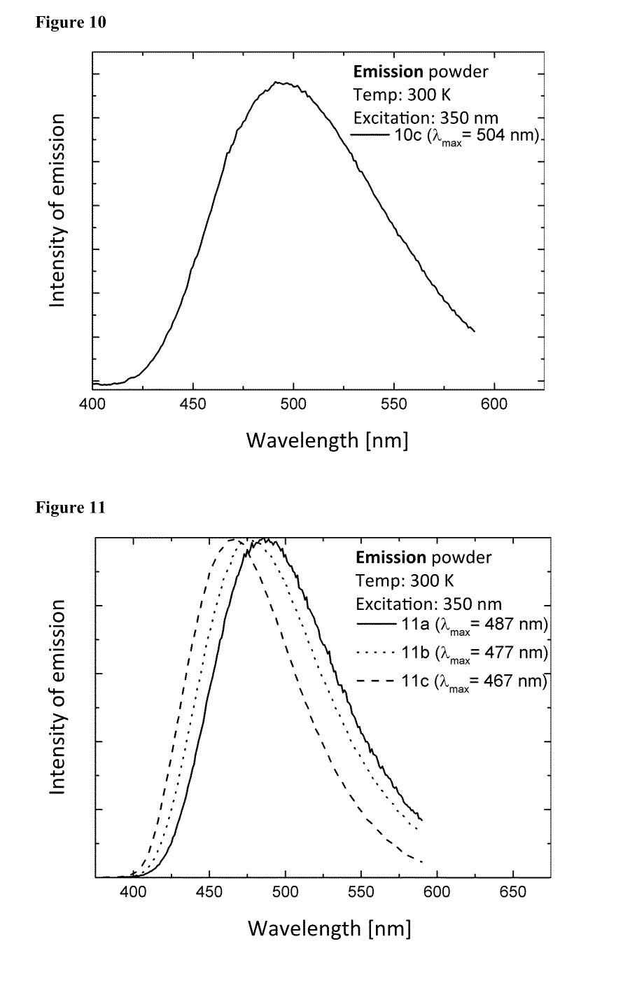

The emission spectra of 11a-11c are shown in FIG. 11.

XII. E∩D=Ph₂PPiperidineN-meta-Fluoro-Benzyl, X=Cl, Br, I: Cu₂Cl₂(Ph₂PPiperidineN-meta-Fluoro-Benzyl)₂ (12a), Cu₂Br₂(Ph₂PPiperidineN-meta-Fluoro-Benzyl)₂ (12b), Cu₂I₂(Ph₂PPiperidineN-meta-Fluoro-Benzyl)₂ (12c)

The compounds 12a-c are fine-crystalline solids.

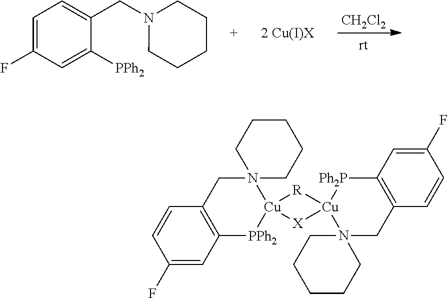

The available compound with X=I was characterized by 1H and 31P NMR spectroscopy and its structure was determined by comparison to the related structures 1a-c, which were confirmed by X-ray diffraction.

12c: ¹H-NMR (CDCl₃, 500 MHz) δ=7.54 (td, 4H), 7.40-7.37 (m, 2H), 7.33-7.30 (m, 4H), 7.25-7.21 (m, 1H), 7.01 (td, 1H), 6.59 (td, 1H), 3.54 (s, 2H), 2.57 (s, 4H), 1.91 (s, 4H), 1.38 (s, 2H) ppm.

³¹P-NMR (CDCl₃): −24 ppm.

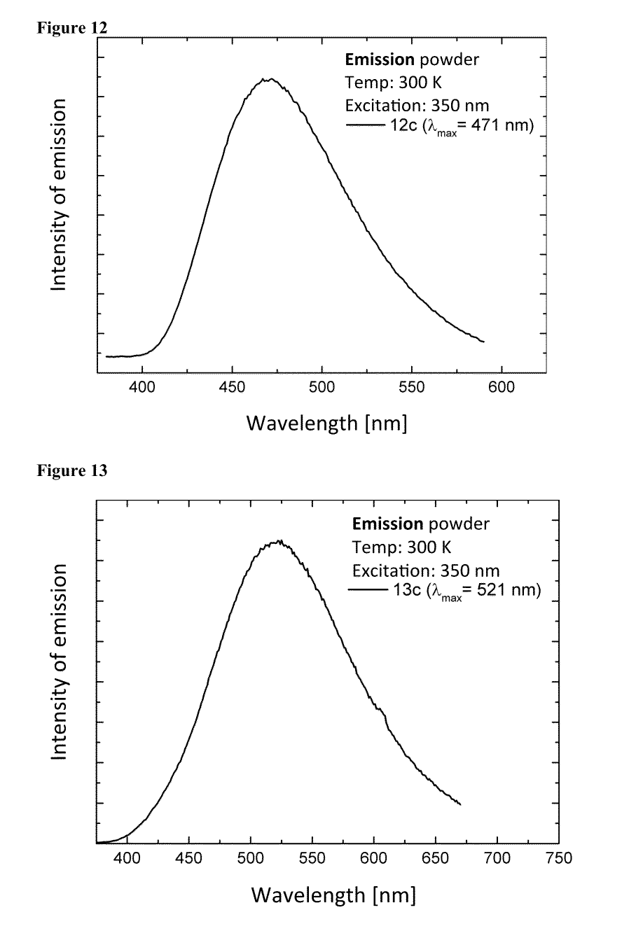

The emission spectrum of 12c is shown in FIG. 12.

XIII. E∩D=Ph₂PPiperidineN-meta-Dimethylamino-Benzyl, X=Cl, Br, I: Cu₂Cl₂(Ph₂PPiperidineN-meta-Dimethylamino-Benzyl)₂ (13a), Cu₂Br₂(Ph₂PPiperidineN-meta-Dimethylamino-Benzyl)₂ (13b), Cu₂I₂(Ph₂PPiperidineN-meta-Dimethylamino-Benzyl)₂ (13c)

The compounds 13a-c are fine-crystalline solids.

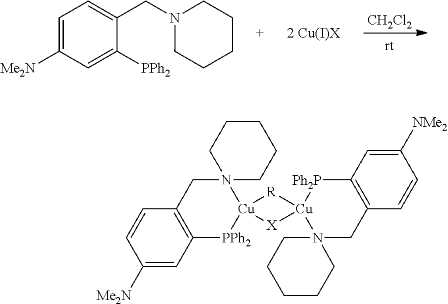

The available compound with X=I was characterized by 1H and 31P NMR spectroscopy and its structure was determined by comparison to the related structures 1a-c, which were confirmed by X-ray diffraction.

13c: ¹H-NMR (CDCl₃, 500 MHz) δ=7.58-7.52 (m, 4H), 7.41-7.33 (m, 6H), 7.07 (dd, 1H), 6.62 (dd, 1H), 6.16 (dd, 1H), 3.48 (s, 2H), 2.72 (s, 6H), 2.58 (s, 4H), 2.00 (s, 4H), 1.49 (s, 2H) ppm.

³¹P-NMR (CDCl₃): −19 ppm.

The emission spectrum of 13c is shown in FIG. 13.

XIV. E∩D=Ph₂PMorpholineNBenzyl, X=Cl, Br, I: Cu₂Cl₂(Ph₂PMorpholineNBenzyl)₂ (14a), Cu₂Br₂(Ph₂P-2,6-dimethylmorpholineNBenzyl)₂ (14b), Cu₂I₂(Ph₂PMorpholineNBenzyl)₂ (14c)

The compounds 14a-c are fine-crystalline solids.

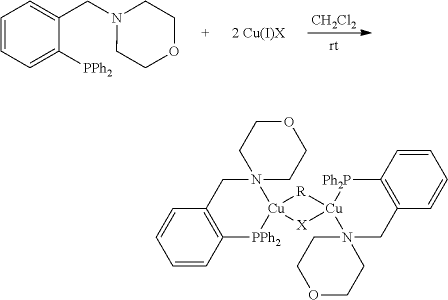

The available compounds were characterized by 1H and 31P NMR spectroscopy and their structure was determined by comparison to the related structures 1a-c, which were confirmed by X-ray diffraction.

14a: EA: ber.: C 60.00; H 5.25; N 3.04,

gef.: C 59.55; H 5.10; N 3.08

14b: EA: ber.: C 54.72; H 4.79, N 2.77,

gef.: C 54.47.55; H 4.70; N 2.89

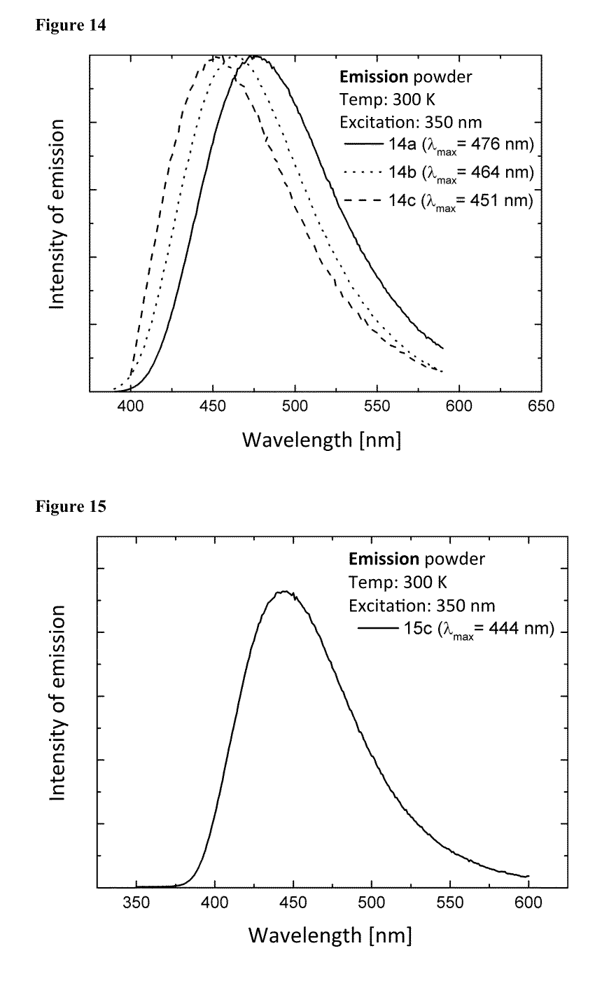

The emission spectra of 14a-14c are shown in FIG. 14.

XV. E∩D=Ph₂P-2,6-dimethylmorpholineNBenzyl, X=Cl, Br, I: Cu₂Cl₂(Ph₂P-2,6-dimethylmorpholineNBenzyl)₂ (15a), Cu₂Br₂(Ph₂P-2,6-dimethylmorpholineNBenzyl)₂ (15b), Cu₂I₂(Ph₂P-2,6-dimethylmorpholineNBenzyl)₂ (15c)

The compounds 15a-c are fine-crystalline solids.

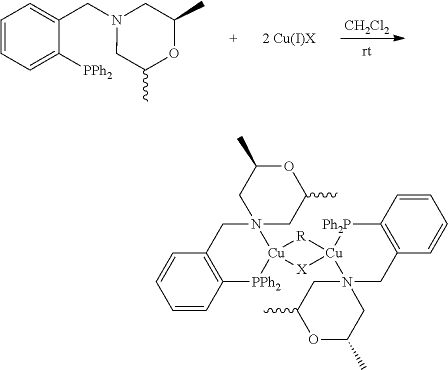

The available compound with X=I was characterized by 1H and 31P NMR spectroscopy and its structure was determined by comparison to the related structures 1a-c, which were confirmed by X-ray diffraction.

15c: ¹H-NMR (CDCl₃, 500 MHz) δ=7.56-7.53 (m, 4H), 7.39-7.35 (m, 3H), 7.31-7.27 (m, 6H), 6.90 (td, 1H), 4.49 (m, 2H), 3.60 (s, 2H), 3.07 (d, 2H), 1.77-1.73 (m, 2H), 1.02 (s, 3H), 1.01 (s, 3H) ppm.

³¹P-NMR (CDCl₃): −24 ppm.

The emission spectrum of 15c is shown in FIG. 15.

XVI. E∩D=Me₂C₄H₆PPhenyleneOPhosphineoxide, X=Cl, Br, I: Cu₂Cl₂(Me₂C₄H₆PPhenylene-OPhosphineoxide)₂ (16a), Cu₂Br₂(Me₂C₄H₆PPhenyleneOPhosphineoxide)₂ (16b), Cu₂I₂(Me₂C₄H₆—PPhenyleneOPhosphineoxide)₂ (16c)

The compounds 16a-c are fine-crystalline solids.

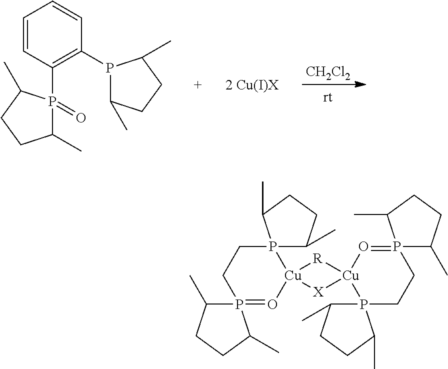

The available compounds with X=Br and X=I were characterized by 1H and 31P NMR spectroscopy, as well as mass spectroscopy and their structure was determined by comparison to the related structures 1a-c, which were confirmed by X-ray diffraction.

16b: ¹H-NMR (CDCl₃, 500 MHz) δ7.62 (ddd, J=31.4, 23.9, 7.2 Hz, 6H), 2.92-2.68 (m, 5H), 2.51-2.21 (m, 9H), 1.98-1.79 (m, 3H), 1.74 (s, 2H), 1.67 (d, J=11.7 Hz, 1H), 1.55-1.25 (m, 16H), 0.94 (dtd, J=37.5, 15.4, 13.4, 7.0 Hz, 11H).

³¹P-NMR (CDCl₃, 202 MHz): δ 73.46, 19.83.

FAB-MS 932 [M]+, 851 [Cu2BrL2]+, 707 [CuL2]+, 466 [CuBrL]+, 385 [CuL]+.

16c: ¹H-NMR (CDCl₃, 500 MHz) δ7.67 (ddd, J=8.1, 5.3, 2.2 Hz, 2H), 7.61-7.48 (m, 4H), 7.41-7.32 (m, 2H), 2.86 (qdd, J=16.7, 8.3, 4.9 Hz, 6H), 2.42-2.11 (m, 11H), 1.83 (qdd, J=12.8, 5.3, 3.1 Hz, 2H), 1.75-1.62 (m, 2H), 1.55-1.24 (m, 16H), 1.02-0.83 (m, 12H).

³¹P-NMR (CDCl₃, 202 MHz): δ 71.76, 9.22.

Elemental analysis found: C, 41.92, H 5.52.

FAB-MS: 1088 [M]+, 899 [Cu2BrL2]+, 707 [CuL2]+, 577 [Cu2IL]+, 512 [CuIL]+, 385 [CuL]+.

### REFERENCES

[i] C. Adachi, M. A. Baldo, S. R. Forrest, S. Lamansky, M. E. Thompson, R. C. Kwong, Appl. Phys. Lett. 2001, 78, 1622.
[ii] X. H. Yang, D. C. Muiller, D. Neher, K. Meerholz, Adv. Mater. 2006, 18, 948; X. H. Yang, D. Neher, Appl. Phys. Lett. 2004, 84, 2476.
[iii] J. Shinar (Hrsg.), Organic light-emitting devices—A survey, AIP-Press, Springer, New York, 2004.
[iv] H. Yersin, Top. Curr. Chem. 2004, 241, 1.
[v] H. Yersin, Highly Efficient OLEDs with Phosphorescent Materials, Wiley-VCH, Weinheim 2008.
[vi] Z. H. Kafafi, Organic Electroluminescence, Taylor & Francis, Boca Raton, 2005.
[vii] M. E. Thompson, P. I. Djurovich, J. Li (University of Southern California, Los Angeles, Calif.), WO 2004/017043 A2, 2004.
[viii] M. E. Thompson, P. I. Djurovich, R. Kwong (University of Southern California, Los Angeles, Calif., Universal Display Corp, Ewing, N.Y.), WO 2004/016711 A1, 2004.
[ix] A. Tsuboyama, S. Okada, T. Takiguchi, K. Ueno, S. Igawa, J. Kamatani, M. Furugori, H. Iwawaki (Canon KK, Tokyo), WO 03/095587 A1, 2003.
[x] C.-M. Che, US 2003/0205707 A1, 2003.
[xi] C.-M. Che, W. Lu, M. C.-W. Chan, US 2002/0179885 A1, 2002.
[xii] J. Kamatani, S. Okada, A. Tsuboyama, T. Takiguchi, S. Igawa, US 2003/186080 A1, 2003.
[xiii] P. Stöβel, I. Bach, A. Büsing (Covion Organic Semiconductors GmbH), DE 10350606 A1, 2005.
[xiv] M. Bold, C. Lennartz, M. Egen, H.-W. Schmidt, M. Thelakkat, M. Bäte, C. Neuber, W. Kowalsky, C. Schildknecht (BASF AG), DE 10338550 A1, 2005.
[xv] C. Lennartz, A. Vogler, V. Pawlowski (BASF AG), DE 10358665 A1, 2005.
[xvi] B. Hsieh, T. P. S. Thoms, J. P. Chen (Canon KK, Tokyo), US 2006/989273 B2, 2006.
[xvii] N. Schulte, S. Heun, I. Bach, P. Stoessel, K. Treacher (Covion Organic Semiconductors), WO 2006/003000 A1, 2006.
[xviii] A. Vogler, V. Pawlowski, H.-W. Schmidt, M. Thelakkat (BASF AG), WO 2006/032449 A1, 2006.
[xix] T. K. Hatwar, J. P. Spindler, R. H. Young (Eastman Kodak Co), WO 2006/028546 A1, 2006.
[xx] P. C. Ford, E. Cariati, J. Bourassa, Chem. Rev. 1999, 99, 3625.
[xxi] H. Araki, K. Tsuge, Y. Sasaki, S. Ishizaka, N. Kitamura, Inorg. Chem. 2007, 46, 10032.
[xxii] A. Rössler, G. Skillas, S. E. Pratsinis, Chemie in unserer Zeit 2001, 35, 32.
[xxiii] Y. Sun, K. Ye, H. Zhang, J. Zhang, L. Zhao, B. Li, G. Yang, B. Yang, Y. Wang, S.-W. Lai, C.-M. Che, Angew. Chem. 2006, 118, 5738.
[xxiv] Y. Chen, J. F. Gerald, L. T. Chadderton, L. Chaffron, Appl. Phys. Lett. 1999, 74, 2782.

1-23. (canceled)

24. A metal(I) complex, comprising a structure of formula A: 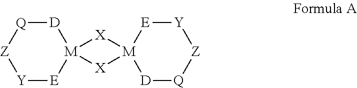
wherein:
M is each independently selected from the group consisting of Cu and Ag;
X is each independently selected from the group consisting of Cl, Br, I, CN, OCN, SCN, alkynyl and N3;
E∩D is each independently a bidentate ligand, wherein:
E=RR′E*, if E*=N, P, As, Sb, or RE*, if E*=C*, O, S, wherein E* is each independently selected from the group consisting of N, P, C*, O, S, As and Sb, and wherein N is no imine nitrogen atom or part of a N-heteroaromatic ring;
D=RR′D*, if D*=N, P, As, Sb, or RD*, if D*=C*, O, S, wherein D* is each independently selected from the group consisting of N, P, C*, O, S, As and Sb, and wherein N is no imine nitrogen atom or part of a N-heteroaromatic ring;
C*=a divalent carbene carbon atom;
R, R′=each independently selected from the group consisting of hydrogen, halogen and substituents which are bound directly or via oxygen (—OR), nitrogen (—NR2), silicon (—SiR3) or sulfur atoms (—SR), alkyl, heteroalkyl, aryl, heteroaryl, alkenyl, alkynyl groups or substituted alkyl, heteroalkyl, aryl, heteroaryl and alkenyl groups comprising substituents selected from halogens, deuterium, alkyl groups, heteroalkyl, aryl, and heteroaryl groups, donor and acceptor groups selected from amines, carboxylates and esters thereof, and CF3-groups; and
wherein D and E differ from each other;
∩=a three-part unit consisting of Q, Y and Z, which are bound to each other and each independently selected from the group consisting of NR, O, S and PR, alkyl, heteroalkyl, aryl, heteroaryl, alkenyl, alkynyl groups or substituted alkyl, heteroalkyl, aryl, heteroaryl and alkenyl groups (with substituents such as halogens or deuterium, alkyl groups, heteroalkyl, aryl, heteroaryl groups), donor and acceptor groups comprising amines, carboxylates and esters thereof, and CF3 groups; and
Q, Y and Z=substituents each independently selected from the group consisting of NR, O, S, PR, alkyl, heteroalkyl, aryl, heteroaryl, alkenyl, alkynyl groups or substituted alkyl, heteroalkyl, aryl, heteroaryl and alkenyl groups comprising substituents selected from halogens, deuterium, alkyl groups, heteroalkyl, aryl, and heteroaryl groups, and donor and acceptor groups selected from amines, carboxylates and esters thereof, and CF₃ groups.

25. The metal(I) complex of claim 24, comprising a structure of one of formula I to IX: 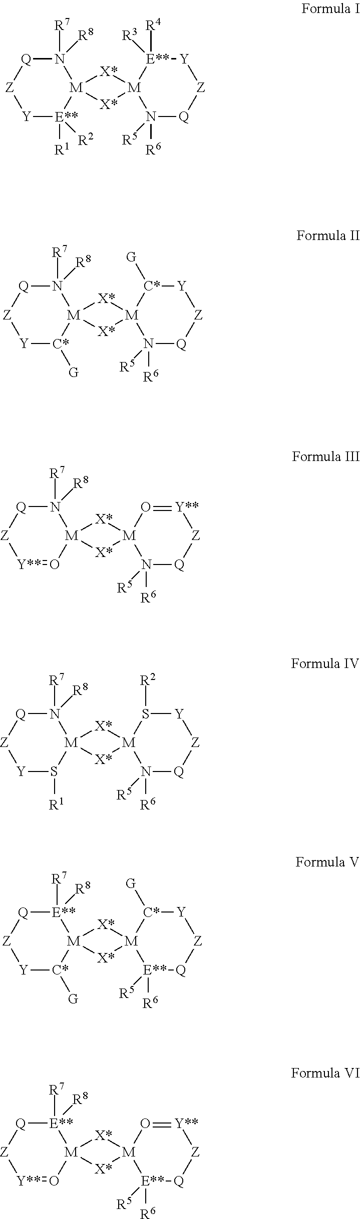 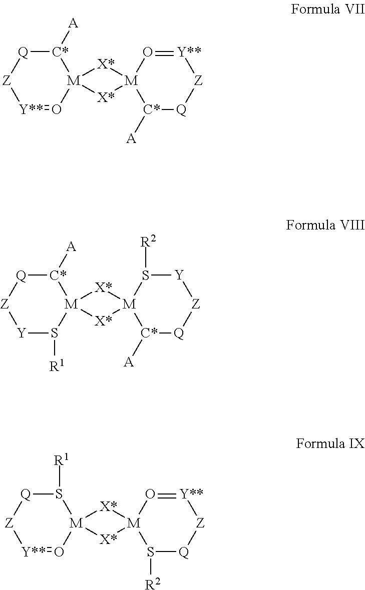
wherein:
X*=each independently selected from the group consisting of Cl, Br, I, CN, OCN, SCN, alkynyl and N₃;
E**=each independently selected from the group consisting of P, As and Sb;
A and G=substituents each independently selected from the group consisting of NRR′, OR, SR, PRR′, alkyl, heteroalkyl, aryl, heteroaryl, alkenyl, alkynyl groups or substituted alkyl, heteroalkyl, aryl, heteroaryl and alkenyl groups comprising substituents selected from halogens, deuterium, alkyl groups, heteroalkyl, aryl, and heteroaryl groups, and donor and acceptor groups comprising amines, carboxylates and esters thereof, and CF₃ groups;
Y**=each independently selected from the group consisting of CR, N, PRR′, SR, and S(O)R;
R¹-R⁸=each independently selected from the group consisting of hydrogen, halogen and substituents which are bound directly or via oxygen (—OR), nitrogen (—NR₂), silicon (—SiR₃) or sulfur atoms (—SR), alkyl, heteroalkyl, aryl, heteroaryl, alkenyl, alkynyl groups or substituted alkyl, heteroalkyl, aryl, heteroaryl and alkenyl groups comprising substituents selected from halogens, deuterium, alkyl groups, heteroalkyl, aryl, and heteroaryl groups, and donor and acceptor groups comprising amines, carboxylates and their esters, and CF₃-groups;
wherein the groups R¹-R⁸ optionally lead to annulated ring systems.

26. The metal(I) complex of claim 25, wherein the unit QC*A is each independently selected from the group consisting of 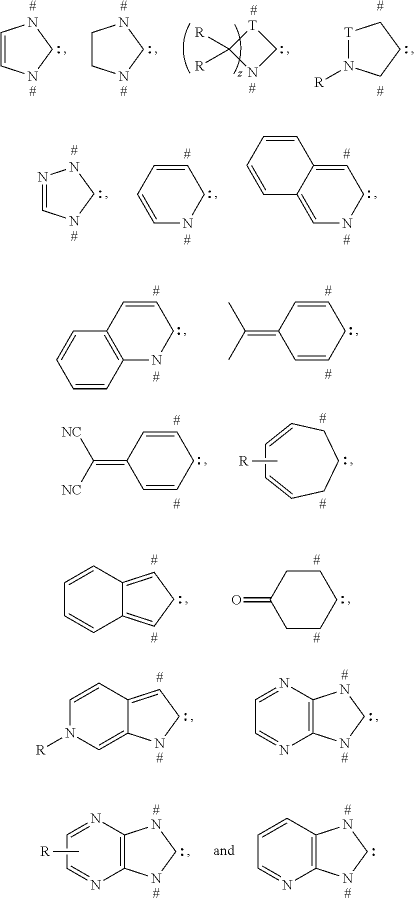
wherein
:=a divalent carbene carbon atom coordinating to the metal atom, and the linkage of Q with Z takes place at one of the positions marked with #, A is the other neighboring atom of the carbene carbon atom, which is substituted with a group R;
T is selected from the group consisting of CR₂, NR and SR; and
z is an integer selected from 1, 2, 3 and 4.

27. The metal(I) complex of claim 25, wherein E∩D is each independently selected from the group consisting of 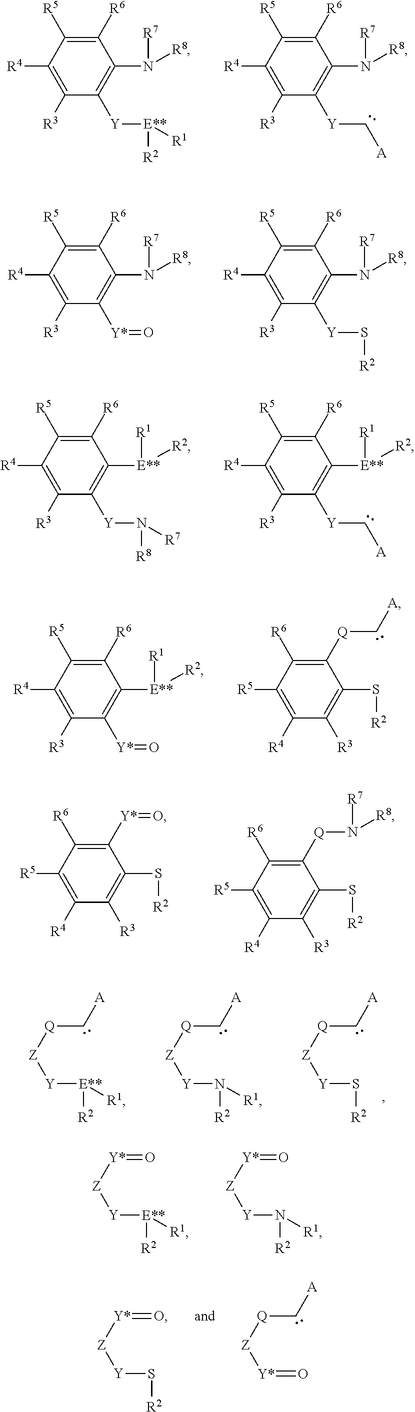
wherein
:=a carbene carbon atom.

28. The metal(I) complex of claim 27, wherein A, Q, G and Y are each bound to each other, and thereby forming one of an imidazolidine and an imidazole derivative, leading with the unit Z to form annulated ring systems, and forming annulated ring systems with the groups R³-R⁸.

29. The metal(I) complex of claim 24, wherein E∩D comprises at least one substituent for increasing the solubility of the metal(I) complex in an organic solvent, the substituent is selected from the group consisting of:
branched, unbranched or cyclic alkyl chains comprising a length of C1 to C30,
branched, unbranched or cyclic alkoxy chains comprising a length of C1 to C30,
branched, unbranched or cyclic perfluoroalkyl chains comprising a length of C1 to C30, and
polyethers comprising a chain length of 3-50 repeat units.

30. The metal(I) complex of claim 24, wherein E∩D comprises at least one substituent selected from the group consisting of electron conductors and hole conductors for increasing charge carrier transport.

31. A method for the production of a metal(I) complex comprising performing a reaction of E∩D with M(I)X, wherein the metal(I) complex comprises a structure of formula A: 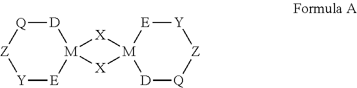
wherein:
M is each independently selected from the group consisting of Cu and Ag;
X is each independently selected from the group consisting of Cl, Br, I, CN, OCN, SCN, alkynyl and N3;
E∩D is each independently a bidentate ligand, wherein:
E=RR′E*, if E*=N, P, As, Sb, or RE*, if E*=C*, O, S, wherein E* is each independently selected from the group consisting of N, P, C*, O, S, As and Sb, and wherein N is no imine nitrogen atom or part of a N-heteroaromatic ring;
D=RR′D*, if D*=N, P, As, Sb, or RD*, if D*=C*, O, S, wherein D* is each independently selected from the group consisting of N, P, C*, O, S, As and Sb, and wherein N is no imine nitrogen atom or part of a N-heteroaromatic ring;
C*=a divalent carbene carbon atom;
R, R′=each independently selected from the group consisting of hydrogen, halogen and substituents which are bound directly or via oxygen (—OR), nitrogen (—NR2), silicon (—SiR3) or sulfur atoms (—SR), alkyl, heteroalkyl, aryl, heteroaryl, alkenyl, alkynyl groups or substituted alkyl, heteroalkyl, aryl, heteroaryl and alkenyl groups comprising substituents selected from halogens, deuterium, alkyl groups, heteroalkyl, aryl, and heteroaryl groups, donor and acceptor groups comprising amines, carboxylates and esters thereof, and CF₃-groups; and
wherein D and E differ from each other;
∩=a three-part unit consisting of Q, Y and Z, which are bound to each other and each independently selected from the group consisting of NR, O, S and PR, alkyl, heteroalkyl, aryl, heteroaryl, alkenyl, alkynyl groups or substituted alkyl, heteroalkyl, aryl, heteroaryl and alkenyl groups (with substituents such as halogens or deuterium, alkyl groups, heteroalkyl, aryl, heteroaryl groups), donor and acceptor groups comprising amines, carboxylates and esters thereof, and CF₃ groups; and
Q, Y and Z=substituents each independently selected from the group consisting of NR, O, S, PR, alkyl, heteroalkyl, aryl, heteroaryl, alkenyl, alkynyl groups or substituted alkyl, heteroalkyl, aryl, heteroaryl and alkenyl groups comprising substituents selected from halogens or deuterium, alkyl groups, heteroalkyl, aryl, and heteroaryl groups, and donor and acceptor groups comprising amines, carboxylates and esters thereof, and CF₃ groups.

32. The method of claim 31, wherein the reaction is performed in one of dichloromethane, acetonitrile, tetrahydrofuran dimethyl sulfoxide, and ethanol.

33. The method of claim 32, further comprising adding one of diethyl ether, pentane, hexane, methyl-tert-butyl ether, methanol, ethanol and water to obtain the metal(I) complex in the form of a solid.

34. The method of claim 33, further comprising substituting at least one bidentate ligand E∩D with at least one substituent for increasing the solubility, selected from the group consisting of:
branched, unbranched or cyclic alkyl chains comprising a length of C1 to C30,
branched, unbranched or cyclic alkoxy chains comprising a length of C1 to C30,
branched, unbranched or cyclic perfluoroalkyl chains comprising a length of C1 to C30, and
polyethers comprising a chain length of 3-50 repeat units.

35. The method of claim 33, further comprising substituting at least one bidentate ligand E∩D with at least one functional group selected from an electron conductor and a hole conductor for improving the charge carrier transport.

36. An optoelectronic component comprising a metal(I) complex, wherein the metal(I) complex comprises a structure of formula A: 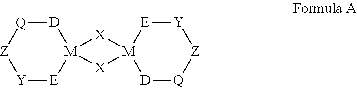
wherein:
M is each independently selected from the group consisting of Cu and Ag;
X is each independently selected from the group consisting of Cl, Br, I, CN, OCN, SCN, alkynyl and N3;
E∩D is each independently a bidentate ligand, wherein:
E=RR′E*, if E*=N, P, As, Sb, or RE*, if E*=C*, O, S, wherein E* is each independently selected from the group consisting of N, P, C*, O, S, As and Sb, and wherein N is no imine nitrogen atom or part of a N-heteroaromatic ring;
D=RR′D*, if D*=N, P, As, Sb, or RD*, if D*=C*, O, S, wherein D* is each independently selected from the group consisting of N, P, C*, O, S, As and Sb, and wherein N is no imine nitrogen atom or part of a N-heteroaromatic ring;
C*=a divalent carbene carbon atom;
R, R′=each independently selected from the group consisting of hydrogen, halogen and substituents which are bound directly or via oxygen (—OR), nitrogen (—NR2), silicon (—SiR3) or sulfur atoms (—SR), alkyl, heteroalkyl, aryl, heteroaryl, alkenyl, alkynyl groups or substituted alkyl, heteroalkyl, aryl, heteroaryl and alkenyl groups comprising substituents selected from halogens, deuterium, alkyl groups, heteroalkyl, aryl, and heteroaryl groups, donor and acceptor groups comprising amines, carboxylates and esters thereof, and CF3-groups; and
wherein D and E differ from each other;
∩=a three-part unit consisting of Q, Y and Z, which are bound to each other and each independently selected from the group consisting of NR, O, S and PR, alkyl, heteroalkyl, aryl, heteroaryl, alkenyl, alkynyl groups or substituted alkyl, heteroalkyl, aryl, heteroaryl and alkenyl groups (with substituents such as halogens or deuterium, alkyl groups, heteroalkyl, aryl, heteroaryl groups), donor and acceptor groups comprising amines, carboxylates and esters thereof, and CF₃ groups; and
Q, Y and Z=substituents each independently selected from the group consisting of NR, O, S, PR, alkyl, heteroalkyl, aryl, heteroaryl, alkenyl, alkynyl groups or substituted alkyl, heteroalkyl, aryl, heteroaryl and alkenyl groups comprising substituents selected from halogens or deuterium, alkyl groups, heteroalkyl, aryl, and heteroaryl groups, and donor and acceptor groups comprising amines, carboxylates and esters thereof, and CF₃ groups.

37. The optoelectronic component of claim 36, wherein the metal(I) complex is used as one of an emitter and an absorber in the range of 1% to 100%.

38. The optoelectronic component of claim 37, wherein the range is 5% to 80%.

39. The optoelectronic component of claim 36, wherein the optoelectronic component is selected from the group consisting of an organic light-emitting component, an organic diode, an organic solar cell, an organic transistor, an organic light-emitting diode, a light-emitting electrochemical cell, an organic field-effect transistor and an organic laser.

40. The optoelectronic component of claim 36, wherein the optoelectronic component is produced by a method comprising applying the metal(I) complex to a carrier.

41. The optoelectronic component of claim 40, wherein the application is performed by one of a wet-chemical process, a colloidal suspension, and a sublimation process.

42. The optoelectronic component of claim 36, wherein the metal(I) complex is introduced into a matrix material for the conduction of electrons or holes in the optoelectronic component, thereby altering one of an emission and an absorption properties of an electronic component.

43. The optoelectronic component of claim 36, wherein the metal(I) complex is used for conversion of one of ultraviolet radiation and blue light to visible light, wherein visible light is one of green light, yellow light and red light.
